(19) United States
(12) Patent Application Publication
(10) Pub. No.: US 2013/0295774 A1
(43) Pub. Date: Nov. 7, 2013

(54) PLASMA ETCHING METHOD

(71) Applicant: TOKYO ELECTRON LIMITED, Tokyo (JP)

(72) Inventors: Akitaka Shimizu, Nirasaki (JP); Masanobu Honda, Nirasaki (JP)

(21) Appl. No.: 13/848,834

(22) Filed: Mar. 22, 2013

Related U.S. Application Data
(62) Division of application No. 13/044,741, filed on Mar. 10, 2011.

(30) Foreign Application Priority Data
Mar. 11, 2010 (JP) 2010-054828

(51) Int. Cl. H01L 21/3065

(52) U.S. Cl. CPC H01L 21/3065
USPC 438/715

(57) ABSTRACT

A plasma etching method performs a plasma etching on a substrate W by irradiating plasma containing charged particles and neutral particles to the substrate W. The method includes controlling a distribution of reaction amounts between the substrate W and the neutral particles in a surface of the substrate W by adjusting a temperature distribution in the surface of the substrate W supported by a support, and controlling a distribution of irradiation amounts of the charged particles in the surface of the substrate W by adjusting a gap between the substrate W supported by the support and an electrode provided so as to face the support.

### CROSS-REFERENCE TO RELATED APPLICATION

This application is a divisional application of application Ser. No. 13/044,741, filed on Mar. 10, 2011, which claims the benefit of Japanese Patent Application No. 2010-054828 filed on Mar. 11, 2010, the entire disclosures of which are incorporated herein by reference.

### FIELD OF THE INVENTION

The present disclosure relates to a plasma etching method for performing a plasma etching on a substrate.

### BACKGROUND OF THE INVENTION

In manufacturing a semiconductor device, as an apparatus for processing a substrate such as a semiconductor wafer (hereinafter, referred to as “wafer”), there has been used a plasma etching apparatus which performs an etching process on the wafer by irradiating plasma to the wafer.

By way of example, a wafer yet to be processed in the above-described plasma etching apparatus is formed of a silicon substrate. On the wafer, a silicon dioxide (SiO₂) film, an etching target film formed of a polysilicon film, a mask film formed of a single layer or multiple layers, a bottom anti-reflective coating BARC, and a photoresist film (hereinafter, referred to as “resist film”) are formed in sequence from the bottom. The resist film is exposed and developed in advance, and a pattern having lines is formed on the resist film. By etching the bottom anti-reflective coating, the mask film, the etching target film in sequence, the pattern having lines is formed on the etching target film. The above-described example in which the etching target film is formed of a polysilicon film may be related to a gate etching process in which an etching target film serves as a gate electrode, for example.

However, recently, in manufacturing a semiconductor device, a wafer becomes larger. As the wafer becomes larger, it becomes difficult to obtain uniformity in line widths CD (critical dimension) and a height of lines formed on the surface of the wafer.

In the above-described etching process, a gas including fluorine, chlorine, oxygen or the like is used as a processing gas. When the wafer is etched, the fluorine, chlorine, oxygen or the like included in the processing gas may be excited into plasma. The plasma includes charged particles (hereinafter, referred to as “ions”) and neutral particles (hereinafter, referred to as “radicals”). The surface of the wafer reacts with the plasma including the ions and radicals, so that a reaction product is generated and the reaction product is volatilized. In this way, the etching process proceeds.

The reaction product generated by the reaction between the surface of the wafer and the plasma may adhere to the lines formed on the wafer again. Therefore, the line widths of the lines formed by the etching process may vary depending on a probability that the reaction product may adhere to the lines again (hereinafter, referred to as “adhesion coefficient”). Since the adhesion coefficient depends on a temperature of the wafer, the line widths of the lines formed on the wafer may vary depending on the temperature of the wafer. Accordingly, there has been suggested a plasma etching apparatus that performs an etching process with high uniformity in line widths of the lines formed on a wafer by controlling a temperature distribution in a surface of the wafer (see, for example, Patent Document 1).

The line widths of the lines formed by performing the etching process may vary depending on a gap between adjacent lines (pattern gap) in addition to the adhesion coefficient. That is, the line widths of the lines formed on the wafer may vary depending on both the temperature of the wafer and the pattern gap.

In this case, it is difficult to independently control the line widths of the lines in an area of a large pattern gap (hereinafter, referred to as “sparse area”) and an area of a small pattern gap (hereinafter, referred to as “dense area”) only by adjusting the temperature of the wafer. However, it may be possible to independently control the line widths of the lines in the sparse area and the dense area only by adjusting a supply amount or composition ratio of a processing gas. Accordingly, there has been suggested a plasma etching apparatus that independently controls the line widths of the lines in a sparse area and a dense area by adjusting a temperature distribution in a surface of a wafer and a supply amount or composition ratio of a processing gas (see, for example, Patent Document 2).
Patent Document 1: Japanese Translation of PCT Application No. 2008-532324
Patent Document 2: Japanese Patent Laid-open Publication No. 2007-081216

However, in case of using the above-described plasma etching apparatuses to perform a plasma etching process, there are some problems as follows.

In the example disclosed in Patent Document 1, if a uniform pattern having only a dense area is required to be formed, it is possible to perform an etching process with high uniformity in line widths of the lines formed on a wafer. However, as described above, when a pattern having both a sparse area and a dense area is required, it is impossible to perform an etching process with high uniformity in line widths of the lines formed on a wafer.

In the example disclosed in Patent Document 2, even when a pattern having a sparse area and a dense area is formed, it is possible to perform an etching process with high uniformity in line widths of lines formed on a wafer. However, if a supply amount of a processing gas as well as a composition ratio thereof is adjusted, there is a change in both a supply amount of radicals and a supply amount of ions. The ions move straightforward and mainly contribute to an etching rate. Thus, it is difficult to control the etching rate to a required level by controlling the supply amount or composition ratio of the processing gas. Consequently, line widths and heights of the lines in the surface of the wafer cannot be uniformed and cross sections of the lines cannot be uniformed.

By way of example, if the mask film includes an organic film, as a processing gas for etching the organic film, it may be possible to use a processing gas such as an oxygen gas (O₂) having a low adhesion coefficient or a low reaction rate between the radicals and the mask film. In case of using the processing gas having the radicals of the low reaction rate, even if the temperature of the wafer and the supply amount or composition ratio of the processing gas are adjusted within a typical variable range, an amount of reacted radicals is hardly changed and the line widths of the lines cannot be controlled.

### BRIEF SUMMARY OF THE INVENTION

In view of the foregoing, the present disclosure provides a plasma etching method and a plasma etching apparatus that independently control distributions of line widths and heights of lines in a surface of a wafer and performs an etching process with high uniformity in cross sectional shapes of lines when the lines are formed by etching a layered mask film including an inorganic film and an organic film or when multiple kinds of line groups having various gaps between adjacent lines are formed by etching a mask film.

In order to solve the above-described problems, the present disclosure provides the following features.

In accordance with one aspect of the present disclosure, there is provided a plasma etching method for performing a plasma etching on a substrate by irradiating plasma containing charged particles and neutral particles to the substrate. The plasma etching method includes controlling a distribution of reaction amounts between the substrate and the neutral particles in a surface of the substrate by adjusting a temperature distribution in the surface of the substrate supported by a support; and controlling a distribution of irradiation amounts of the charged particles in the surface of the substrate by adjusting a gap between the substrate supported by the support and an electrode provided so as to face the support.

In accordance with another aspect of the present disclosure, there is provided a plasma etching apparatus configured to perform a plasma etching on a substrate by irradiating plasma containing charged particles and neutral particles to the substrate. The plasma etching apparatus includes a support capable of supporting the substrate; an electrode provided so as to face the support; a temperature distribution adjusting unit capable of adjusting a temperature distribution in a surface of the substrate supported by the support; a gap adjusting unit capable of adjusting a gap between the substrate supported by the support and the electrode; and a controller capable of controlling a distribution of reaction amounts between the substrate and the neutral particles in the surface of the substrate by adjusting the temperature distribution by the temperature distribution adjusting unit and capable of controlling a distribution of irradiation amounts of the charged particles in the surface of the substrate by adjusting the gap by the gap adjusting unit.

In accordance with the present disclosure, it is possible to independently control distributions of widths and heights of lines in a surface of a wafer and it is also possible to perform an etching process with high uniformity in cross sectional shapes of lines when the lines are formed by etching a layered mask film including an inorganic film and an organic film or when multiple kinds of line groups having various gaps between adjacent lines are formed by etching a mask film.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a cross sectional view showing a schematic configuration of a plasma etching apparatus in accordance with a first embodiment and showing a status of an upper electrode located at a retreat position;

FIG. 2 is a cross sectional view showing a schematic configuration of the plasma etching apparatus in accordance with the first embodiment and showing a status of the upper electrode located at a process position;

FIGS. 3A and 3B provide explanatory diagrams simply showing an upper electrode driving unit;

FIG. 4 is a transversal cross sectional view of the upper electrode;

FIG. 5 is a diagram for explaining a schematic configuration of a gas supply apparatus;

FIG. 6 is a flowchart for explaining a sequence of processes of a plasma etching method in accordance with the first embodiment;

FIGS. 7A to 7E are cross sectional views schematically showing wafer states in each process of the plasma etching method in accordance with the first embodiment;

FIGS. 8A to 8C are graphs showing distributions of etching rates ER in a longitudinal direction on a surface of a wafer when a gap G is adjusted;

FIGS. 9A to 9D are graphs schematically showing temperature dependency of line widths CD of line groups and gap dependency of an etching rate ER in a longitudinal direction during a second mask film etching process;

FIGS. 10A to 10D are graphs schematically showing temperature dependency of line widths CD of line groups and gap dependency of an etching rate ER in a longitudinal direction during a first mask film etching process;

FIG. 11 is a cross sectional view showing a schematic configuration of a plasma etching apparatus in accordance with a second embodiment and showing a status of an upper electrode located at a retreat position;

FIG. 12 is a cross sectional view showing a schematic configuration of the plasma etching apparatus in accordance with the second embodiment and showing a status of the upper electrode located at a process position;

FIGS. 13A and 13B provide explanatory diagrams simply showing an upper electrode driving unit;

FIG. 14 is a transversal cross sectional view of the upper electrode;

FIG. 15 is a diagram for explaining a schematic configuration of a gas supply apparatus;

FIG. 16 is a flowchart for explaining a sequence of processes of a plasma etching method in accordance with the second embodiment;

FIGS. 17A to 17E are cross sectional views schematically showing statuses of a wafer in each process of the plasma etching method in accordance with the second embodiment; and

FIGS. 18A to 18C are graphs schematically showing temperature dependency of line widths CD of line groups and gap dependency of an etching rate ER in a longitudinal direction in the second embodiment.

### DETAILED DESCRIPTION OF THE INVENTION

Hereinafter, embodiments of the present disclosure will be described with reference to the accompanying drawings.

### First Embodiment

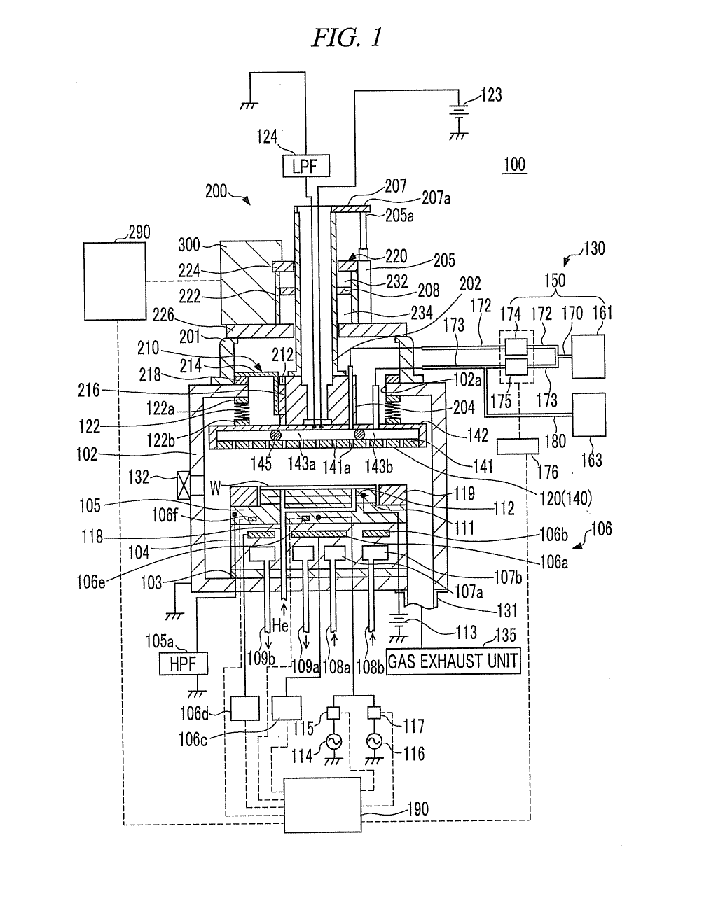

Referring to FIGS. 1 to 10D, a plasma etching method and a plasma etching apparatus in accordance with a first embodiment of the present disclosure will be explained.

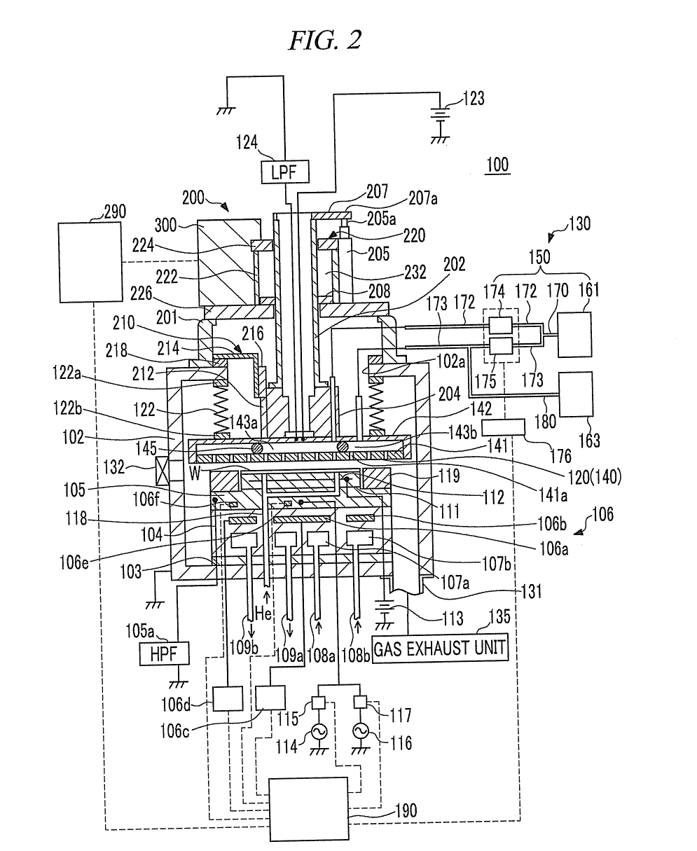

First of all, referring to FIGS. 1 and 2, a plasma etching apparatus in accordance with the present embodiment will be explained. FIGS. 1 and 2 are cross sectional views showing schematic configurations of the plasma etching apparatus in accordance with the present embodiment. FIG. 1 shows a configuration in which an upper electrode is located at a retreat position, and FIG. 2 shows a configuration in which the upper electrode is located at a process position.

A plasma etching apparatus 100 in accordance with the present embodiment is configured as a parallel plate type plasma etching apparatus, for example.

The plasma etching apparatus 100 includes a cylindrical chamber (processing vessel) 102 made of, for example, aluminum of which surface is anodically oxidized (alumite treated). The chamber 102 is grounded.

A susceptor support 104 formed in a substantially columnar shape is provided at a bottom of the chamber 102 via an insulating plate 103 made of ceramic. Further, provided on the susceptor support 104 is a susceptor 105 serving as a lower electrode. The susceptor 105 is connected with a high pass filter HPF 105a.

The susceptor 105 is formed to have a protruded circular plate shape in an upper central area thereof, and an electrostatic chuck 111 having substantially the same size as a wafer W is provided on the susceptor 105. The electrostatic chuck 111 is formed of an insulating member having an electrostatic electrode 112 embedded therein. The electrostatic chuck 111 is made of a circular plate-shaped ceramic material, and the electrostatic electrode 112 is connected with a DC power supply 113. If a positive DC voltage is applied to the electrostatic electrode 112, a negative potential is generated at a surface of the wafer W on the electrostatic chuck 111's side (hereinafter, referred to as “rear surface”), so that there is generated a potential difference between the electrostatic electrode 112 and the rear surface of the wafer W. The wafer W is attracted to and held on the electrostatic chuck 111 by Coulomb force or Johnsen-Rahbek force caused by the potential difference. By way of example, a DC voltage of about 1.5 kV is applied to the electrostatic chuck 111 from the DC power supply 113 connected with the electrostatic electrode 112. Thus, the wafer W is electrostatically attracted to the electrostatic chuck 111.

Further, the susceptor support 104 and the susceptor 105 serve as a supporting member of the present disclosure.

The susceptor 105 is connected with a first high frequency power supply 114 via a first matching unit 115 and a second high frequency power supply 116 via a second matching unit 117. The first high frequency power supply 114 applies a bias power, which is a high frequency power having a relatively low frequency of, for example, about 13.6 MHz, to the susceptor 105. The second high frequency power supply 116 applies a power for plasma generation, which is a high frequency power having a relatively high frequency of, for example, about 40 MHz, to the susceptor 105. The susceptor 105 applies the power for plasma generation to the inside of the chamber 102.

Furthermore, provided through the insulating plate 103, the susceptor support 104, the susceptor 105, and the electrostatic chuck 111 is a gas passage 118 for supplying a heat transfer medium (for example, a backside gas such as a He gas) to the rear surface of the wafer W as a target object to be processed. Heat is transferred between the susceptor 105 and the wafer W through this heat transfer medium, so that the wafer W is maintained at a predetermined temperature.

An annular focus ring 119 is provided at an upper periphery of the susceptor 105 so as to surround the wafer W supported on the electrostatic chuck 111. The focus ring 119 is made of a dielectric material such as ceramic or quartz or a conductive material such as single crystalline silicon which is the same as a material of the wafer W. Therefore, a distribution region of the plasma is extended from the wafer W to the focus ring 119, so that plasma density above an outer peripheral area of the wafer W can be maintained at substantially the same level as plasma density above a central area of the wafer W. Thus, plasma etching uniformity in the surface of the wafer W can be improved.

There will be explained a temperature distribution adjusting unit 106 which adjusts a temperature distribution in the surface of the wafer W supported on the susceptor 105. The temperature distribution adjusting unit 106 includes heaters 106a and 106b, heater power supplies 106c and 106d, thermometers 106e and 106f, and coolant paths 107a and 107b.

Within the susceptor support 104, the central heater 106a is provided at a central area and the outer peripheral heater 106b is provided at an outer peripheral area. The central heater 106a is connected with the central heater power supply 106c and the outer peripheral heater 106b is connected with the outer peripheral heater power supply 106d. Each of the central heater power supply 106c and the outer peripheral heater power supply 106d independently controls a power applied to the central heater 106a and the outer peripheral heater 106b, so that it is possible to control a temperature distribution of the susceptor support 104 and the susceptor 105 in a radial direction. Thus, it is possible to control a temperature distribution of the wafer W in a radial direction.

Further, within the susceptor support 104, the central thermometer 106e and the outer peripheral thermometer 106f are provided. The central thermometer 106e and the outer peripheral thermometer 106f measure temperatures of the central area and the outer peripheral area of the susceptor support 104. Thus, temperatures at a central area and an outer peripheral area of the wafer W can be calculated. The temperatures measured by the central thermometer 106e and the outer peripheral thermometer 106f are transmitted to an apparatus controller 190. The apparatus controller 190 adjusts output of the central heater power supply 106c and the outer peripheral heater power supply 106d such that the wafer W's temperature calculated from the measured temperatures becomes a target temperature.

Furthermore, within the susceptor support 104, the central coolant path 107a may be provided at the central area and the outer peripheral coolant path 107b may be provided at the outer peripheral area. By way of example, cooling water and fluorocarbon-based coolant having different temperatures from each other may be circulated in the coolant paths 107a and 107b, respectively. In this case, a coolant is introduced to the central coolant path 107a through a central inlet line 108a; circulated in the central coolant path 107a; and then discharged through a central outlet line 109a. Meanwhile, a coolant is introduced to the outer peripheral coolant path 107b through an outer peripheral inlet line 108b; circulated in the outer peripheral coolant path 107b; and then discharged through an outer peripheral outlet line 109b.

A temperature of the susceptor 105 is adjusted by heating by the heaters 106a and 106b and cooling by the coolants. Therefore, the wafer W is adjusted to a preset temperature by a heat transfer from the susceptor 105 as well as a radiation heat transfer from the plasma or irradiation of the ions contained in the plasma. In the present embodiment, the susceptor support 104 includes the central heater 106a and the central coolant path 107a at the central area and the outer peripheral heater 106b and the outer peripheral coolant path 107b at the outer peripheral area. Therefore, the temperatures at the central area and the outer peripheral area of the wafer W can be adjusted independently, and the temperature distribution in the surface of the wafer W can be adjusted.

There may be a non-illustrated space between the central heater 106a and the outer peripheral heater 106b or between the central coolant path 107a and the outer peripheral coolant path 107b, and the space may serve as a heat insulating layer. The heat insulating layer thermally isolates the central heater 106a from the outer peripheral heater 106b or the central coolant path 107a from the outer peripheral coolant path 107b so that it is easy to make a great temperature difference between the central area of the wafer W and the outer peripheral area of the wafer W.

An upper electrode 120 facing the susceptor 105 in parallel is provided above the susceptor 105. The upper electrode 120 can be moved in one direction, for example, in a vertical direction, by an upper electrode driving unit 200. Since the upper electrode 120 can be moved in the vertical direction, a thickness of a space between the upper electrode 120 and the susceptor 105, i.e., a distance G (hereinafter, referred to as “gap”) between the upper electrode 120 and the susceptor 105 can be adjusted. By adjusting the gap G, plasma can be distributed appropriately in the space between the upper electrode 120 and the susceptor 105 in the chamber 102 as described below. Further, it is possible to adjust a distribution of a plasma irradiation amount to the surface of the wafer W supported on the susceptor 105.

A maximum value of a vertical moving amount of the upper electrode 120 driven by the upper electrode driving unit 200 can be set to be, for example, about 70 mm. In this case, the gap G can be adjusted within a range of about 20 mm to about 90 mm.

The plasma etching apparatus may have a configuration rotated 90 degrees from the configurations illustrated in FIGS. 1 and 2 or may have an upside-down configuration thereof. Further, the upper electrode 120 serves as an electrode of the present disclosure. The upper electrode driving unit 200 serves as a gap adjusting unit of the present disclosure.

The upper electrode 120 is supported by an upper inner wall of the chamber 102 via a bellows 122. The bellows 122 is fixed to the upper inner wall of the chamber 102 via an annular upper flange 122a by a fixing member such as a bolt and fixed to a surface of the upper electrode 120 via an annular lower flange 122b by a fixing member such as a bolt.

The upper electrode 120 is connected with a DC power supply 123. Further, the upper electrode 120 is connected with a low pass filter LPF 124.

A bottom area of the chamber 102 is connected with a gas exhaust pipe 131 and the gas exhaust pipe 131 is connected with a gas exhaust unit 135. The gas exhaust unit 135 includes a vacuum pump such as a turbo-molecular pump and adjusts the internal pressure of the chamber 102 to a preset depressurized atmosphere (for example, about 0.67 Pa or less). Further, a gate valve 132 is installed at a sidewall of the chamber 102. By opening the gate valve 132, the wafer W can be loaded into the chamber 102 and unloaded from the chamber 102. Furthermore, by way of example, when the wafer W is transferred, a transfer arm may be used.

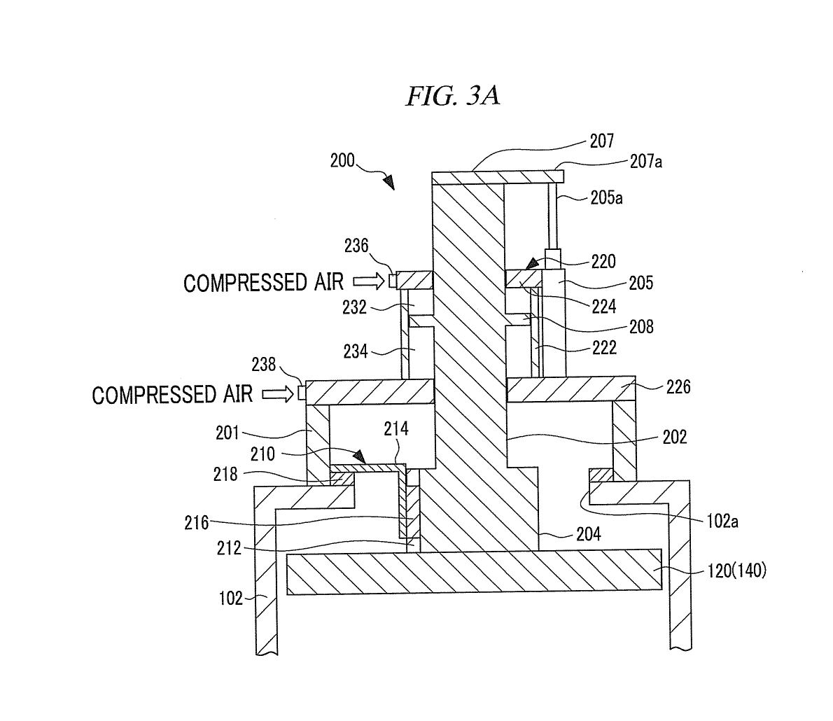

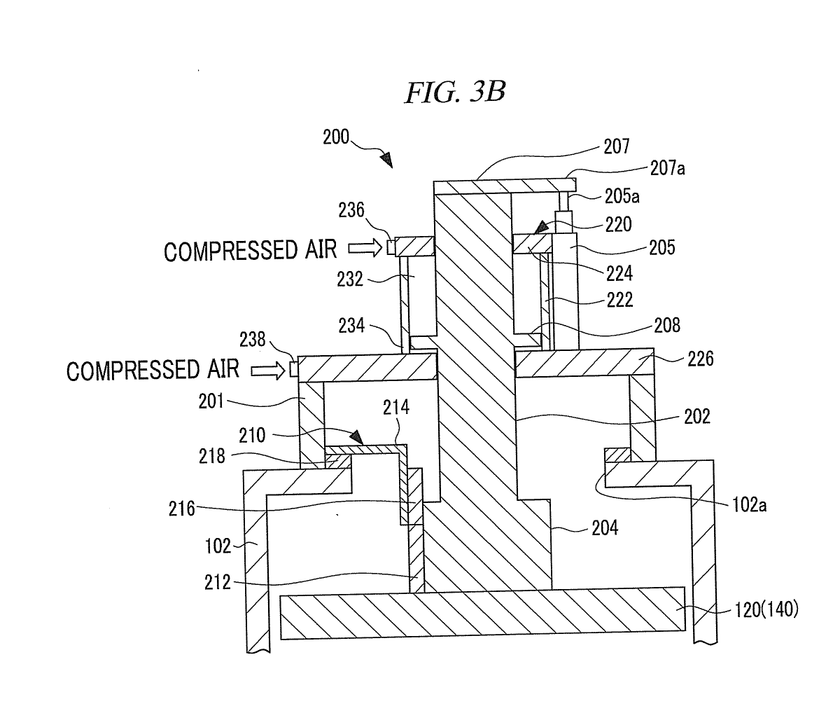

Hereinafter, a configuration of the upper electrode driving unit 200 will be explained in detail with reference to FIGS. 3A and 3B. FIGS. 3A and 3B provide explanatory diagrams simply showing the upper electrode driving unit. To be specific, FIG. 3A shows the upper electrode driving unit located at a retreat position, and FIG. 3B shows the upper electrode driving unit located at a process position.

The upper electrode driving unit 200 includes a substantially cylindrical support member 204 which supports the upper electrode 120. The support member 204 is fixed at an approximate center of the top of the upper electrode 120 by a bolt or the like.

The support member 204 is installed so as to be allowed to enter a hole 102a formed at an approximate center of an upper wall of the chamber 102. To be specific, an outer surface of the support member 204 is supported at an inner wall of the hole 102a of the chamber 102 via a slide mechanism 210.

By way of example, the slide mechanism 210 includes a guide member 216 fixed to a vertical part of a fixing member 214 having an L-shaped cross section at an upper area of the chamber 102; and a rail 212 provided on the outer surface of the support member 204 in one direction (vertical direction in the present embodiment) and supported by the guide member 216 so as to be slidably moved.

The fixing member 214 that fixes the guide member 216 of the slide mechanism 210 has a horizontal part which is fixed at the upper area of the chamber 102 via an annular horizontal position adjusting plate 218. The horizontal position adjusting plate 218 is configured to adjust a horizontal position of the upper electrode 120. By way of example, the horizontal position adjusting plate 218 is fixed to the chamber 102 by a multiple number of bolts arranged at a same interval in a circumferential direction of the horizontal position adjusting plate 218, and an inclination of the horizontal position adjusting plate 218 with respect to a horizontal direction may be adjusted by a protruded height of the bolts. By adjusting the inclination of the horizontal position adjusting plate 218 with respect to the horizontal direction, an inclination of the guide member 216 of the slide mechanism 210 with respect to a vertical direction can be adjusted. Therefore, an inclination of the upper electrode 120 supported via the guide member 216 with respect to a horizontal direction can be adjusted. Consequently, a horizontal position of the upper electrode 120 can be maintained all the time by a simple manipulation.

A pneumatic cylinder 220 for driving the upper electrode 120 is provided above the chamber 102 via a cylindrical body 201. A lower end of the cylindrical body 201 is airtightly sealed so as to cover the hole 102a of the chamber 102 and an upper end of the cylindrical body 201 is airtightly sealed with a lower end of the pneumatic cylinder 220.

The pneumatic cylinder 220 includes a rod 202 which can be moved in one direction. A lower end of the rod 202 is connected with an approximate center of the top of the support member 204 by a bolt or the like. By driving the rod 202 of the pneumatic cylinder 220, the upper electrode 120 is moved by the support member 204 in one direction along with the slide mechanism 210. The rod 202 is formed in a cylinder shape and an inner space of the rod 202 communicates with a center hole formed at an approximate center of the support member 204 so as to be opened to the atmosphere. Therefore, a line for grounding the upper electrode 120 via the low pass filter LPF 124 and a power supply line for applying a DC voltage from the DC power supply 123 to the upper electrode 120 may be connected with the upper electrode 120 via the inner space of the rod 202 and the center hole of the support member 204.

By way of example, provided at a side area of the pneumatic cylinder 220 is a linear encoder 205 as a position detection unit for detecting a position of the upper electrode 120. Meanwhile, provided at an upper end of the rod 202 of the pneumatic cylinder 220 is an upper end member 207 having an extended part 207a extended from the rod 202 in a lateral direction. The extended part 207a of the upper end member 207 is in contact with a detector 205a of the linear encoder 205. Since the upper end member 207 is moved along with the upper electrode 120, a position of the upper electrode 120 can be detected by the linear encoder 205.

The pneumatic cylinder 220 includes a cylinder main body 222 between an upper support plate 224 and a lower support plate 226. Provided on an outer surface of the rod 202 is an annular partition member 208 which divides the inside of the pneumatic cylinder 220 into an upper space 232 and a lower space 234.

As depicted in FIGS. 3A and 3B, compressed air is introduced from an upper port 236 of the upper support plate 224 into the upper space 232 of the pneumatic cylinder 220. Further, compressed air is introduced from a lower port 238 of the lower support plate 226 into the lower space 234 of the pneumatic cylinder 220. By controlling an amount of the air introduced from the upper port 236 and the lower port 238 into the upper space 232 and the lower space 234, respectively, it is possible to control the rod 202 to be moved in one direction (vertical direction in this embodiment). The amount of the air introduced to the pneumatic cylinder 220 is controlled by a pneumatic circuit 300 provided in the vicinity of the pneumatic cylinder 220.

The upper electrode driving unit 200 includes a controller 290 and the controller 290 is connected with the apparatus controller 190. A control signal from the apparatus controller 190 is transmitted to the controller 290 and each component of the upper electrode driving unit 200 is controlled by the controller 290.

Hereinafter, there will be explained a supply amount distribution adjusting unit 130 that adjusts a distribution of a supply amount of a plasma gas supplied to the wafer W supported on the susceptor 105. The supply amount distribution adjusting unit 130 includes a shower head 140 configured as one body with the upper electrode 120, and a gas supply apparatus 150.

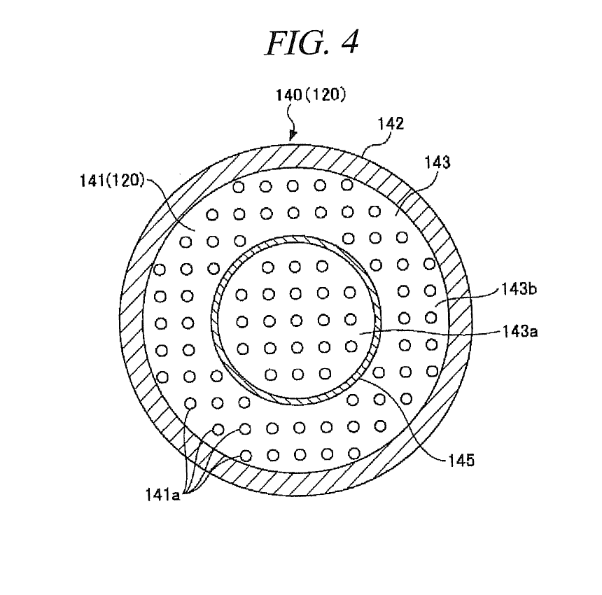

Referring to FIGS. 1, 2 and 4, a configuration of the shower head 140 will be explained. FIG. 4 is a transversal cross sectional view of the upper electrode.

The shower head 140 is configured to supply a mixed gas onto the wafer W supported on the susceptor 105. The shower head 140 includes a circular electrode plate 141 (upper electrode 120) having a multiple number of gas discharge holes 141a and an electrode support body 142 which supports an upper surface of the electrode plate 141 and is detachable therefrom. The electrode support body 142 is formed in a circular plate shape having the same diameter as the electrode plate 141 and includes a circular buffer room 143 therein. By way of example, as depicted in FIG. 4, in the buffer room 143, an annular partition wall member 145 formed of an O-ring is installed and divides the buffer room 143 into a first buffer room 143a on a central side and a second buffer room 143b on an outer peripheral side. The first buffer room 143a faces a central area of the wafer W on the susceptor 105 and the second buffer room 143b faces an outer peripheral area of the wafer W on the susceptor 105. Bottom surfaces of the respective buffer rooms 143a and 143b communicate with the gas discharge holes 141a, and the mixed gas may be discharged from the first buffer room 143a toward the central area of the wafer W and from the second buffer room 143b toward the outer peripheral area of the wafer W. Further, the mixed gas is supplied to the buffer rooms 143a and 143b by the gas supply apparatus 150.

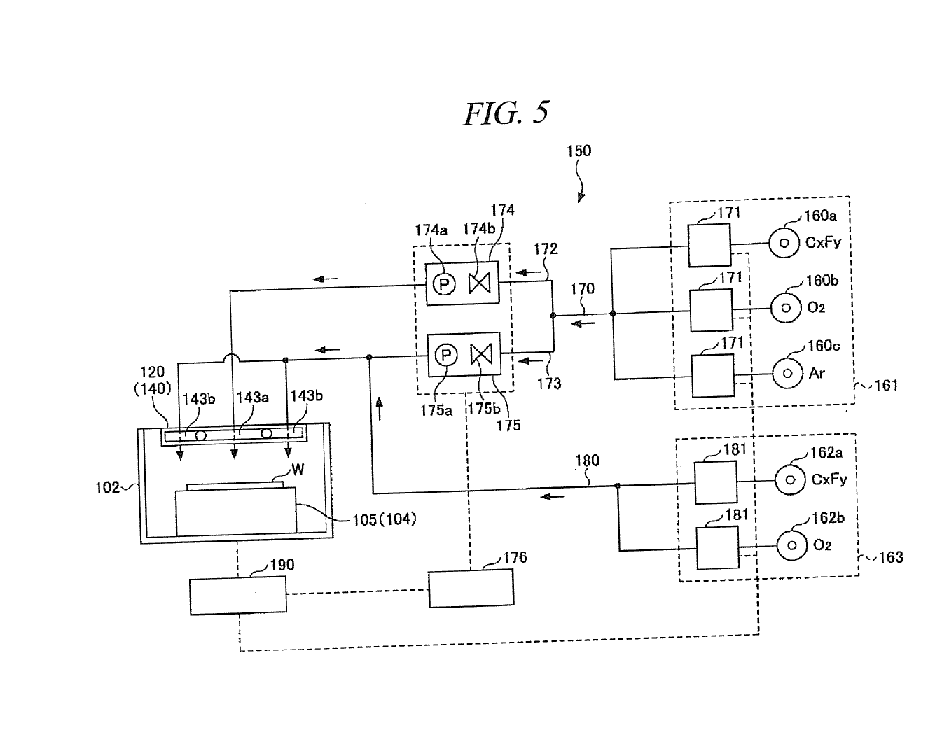

Hereinafter, referring to FIGS. 1, 2 and 5, the gas supply apparatus 150 will be explained. FIG. 5 is a diagram for explaining a schematic configuration of the gas supply apparatus.

As depicted in FIG. 5, the gas supply apparatus 150 includes a first gas box 161 which accommodates a multiple number of, for example, three gas supply sources 160a, 160b, and 160c and a second gas box 163 which accommodates a multiple number of, for example, two additional gas supply sources 162a and 162b. In the present embodiment, by way of example, a fluorocarbon-based fluorine compound as a processing gas, for example, CₓF_{y} such as CF₄, C₄F₆, C₄F₈, and C₈F₈ is sealed in the gas supply source 160a. Further, by way of example, an oxygen (O₂) gas as a gas for controlling adhesion of a CF-based reaction product is sealed in the gas supply source 160b. A rare gas as a carrier gas, for example, an Ar gas is sealed in the gas supply source 160c. By way of example, a CₓF_{y} gas capable of promoting an etching process is sealed in the additional gas supply source 162a, and an oxygen (O₂) gas capable of controlling adhesion of a CF-based reaction product is sealed in the additional gas supply source 162b.

Each of the gas supply sources 160a to 160c of the first gas box 161 is connected with a mixing line 170 where various gases from each of the gas supply sources 160a to 160c are joined and mixed together. In the mixing line 170, a mass flow controller 171 for adjusting a flow rate of a gas from each of the gas supply sources 160a to 160c is provided for each gas supply source. The mixing line 170 is connected with a first branch line 172 and a second branch line 173 which divide the mixed gas mixed at the mixing line 170. The first branch line 172 is connected with the first buffer room 143a of the shower head 140. The second branch line 173 is connected with the second buffer room 143b of the shower head 140.

A pressure adjusting unit 174 is installed on the first branch line 172. In the same manner, a pressure adjusting unit 175 is installed on the second branch line 173. The pressure adjusting unit 174 includes a pressure gauge 174a and a valve 174b. Likewise, the pressure adjusting unit 175 includes a pressure gauge 175a and a valve 175b. A measurement result measured by the pressure gauge 174a of the pressure adjusting unit 174 and a measurement result measured by the pressure gauge 175a of the pressure control unit 175 may be outputted to a pressure control apparatus 176. The pressure control apparatus 176 adjusts an opening/closing degree of each valve 174b or 175b based on the measurement results of the pressure gauges 174a and 175a and controls a pressure ratio, i.e., a flow rate ratio of the mixed gas in the first branch line 172 and the second branch line 173. Further, when setting a supplied gas, the pressure control apparatus 176 may adjusts the pressure ratio of the mixed gas flowing through the first branch line 172 and the second branch line 173 to a preset target pressure ratio in a state where an additional gas is not supplied from the second gas box 163, which will be described later, to the second branch line 173 and the pressure control apparatus 176 may set opening/closing degrees of the valves 174b and 175b in that state.

Each additional gas supply source 162a or 162b of the second gas box 163 is connected with an additional gas supply line 180 communicating with, for example, the second branch line 173. By way of example, the additional gas supply line 180 is connected with each additional gas supply source 162a or 162b and the additional gas supply line 180 is connected with the second branch line 173 on the way. The additional gas supply line 180 is connected with a downstream side of the pressure adjusting unit 175. On the additional gas supply line 180, a mass flow controller 181 for controlling a flow rate of an additional gas from each additional gas supply source 162a or 162b is provided for each additional gas supply source. With this configuration, the additional gases from the second gas box 163 may be selected and mixed together to be supplied to the second branch line 173.

Operations of the mass flow controller 171 in the first gas box 161 and the mass flow controller 181 in the second gas box 163 are controlled by, for example, the apparatus controller 190, which will be described later, of the plasma etching apparatus 100. Accordingly, the apparatus controller 190 may control a start and a stop of supply of various gases from the first gas box 161 and the second gas box 163, and control supply amounts of various gases.

Further, the second gas box 163 and the additional gas supply line 180 may be omitted from the gas supply apparatus 150.

The plasma etching apparatus 100 includes the apparatus controller 190. The apparatus controller 190 includes a non-illustrated operation processing unit such as a CPU and a non-illustrated storage medium such as a hard disk. The apparatus controller 190 controls an operation of each component such as the first high frequency power supply 114, the second high frequency power supply 116, the temperature distribution adjusting unit 106, the upper electrode driving unit 200, or the supply amount distribution adjusting unit 130. Further, by way of example, when the apparatus controller 190 controls the operation of each component, the CPU of the apparatus controller 190 controls the operation of each component according to a program corresponding to each etching process which is stored in, for example, the hard disk of the apparatus controller 190.

The apparatus controller 190 serves as a controller of the present disclosure.

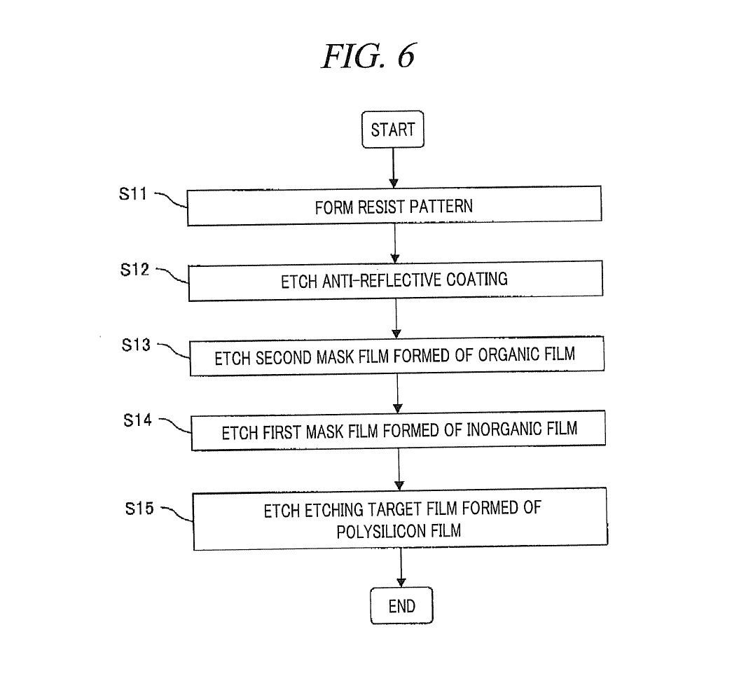

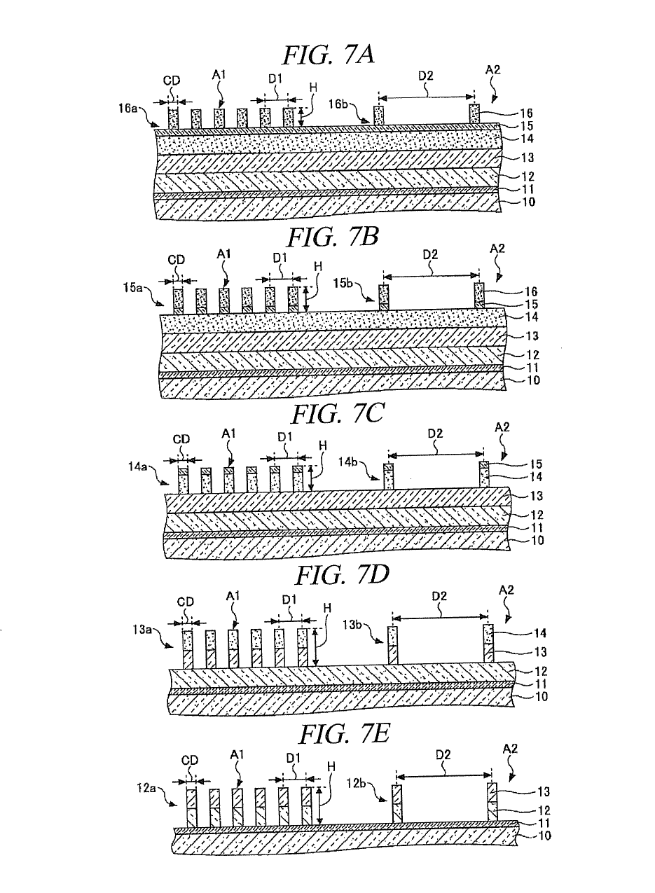

Hereinafter, referring to FIG. 6 and FIGS. 7A to 7E, there will be explained a plasma etching method using the plasma etching apparatus 100. FIG. 6 is a flowchart for explaining a sequence of processes of a plasma etching method in accordance with the present embodiment. FIGS. 7A to 7E are cross sectional views schematically showing statuses of a wafer in each process of the plasma etching method in accordance with the present embodiment.

As depicted in FIG. 6, the plasma etching method in accordance with the present embodiment includes a resist pattern forming process (step S11), an anti-reflective coating etching process (step S12), a second mask film etching process (step S13), a first mask film etching process (step S14), and an etching target film etching process (step S15).

Further, the second mask film etching process (step S13) and the first mask film etching process (step S14) are included in an etching process of the present disclosure.

Above all, the resist pattern forming process (step S11) is performed. In the resist pattern forming process (step S11), a resist pattern having line groups 16a and 16b formed of a resist film 16 is formed on a surface of a wafer W on which a second mask film 14 is already formed via a first mask film 13. FIG. 7A shows a wafer state in the resist pattern forming process (step S11).

Herein, a line group is a structure extended in a certain direction and spaced apart from an adjacent line group in a direction orthogonal to the extended direction when viewed from the top.

There is prepared in advance a substrate in which an insulating film 11, an etching target film 12, a first mask film 13, a second mask film 14, and an anti-reflective coating 15 are formed in sequence from the surface of a wafer 10 made of, for example, a silicon.

The etching target film 12 is a film to be etched finally in the plasma etching method in accordance with the present embodiment. By way of example, the insulating film may be a silicon oxide (SiO₂) film made of, e.g., tetraethoxysilane (TEOS) serving as a gate insulating film, and the etching target film 12 after an etching process may be a polysilicon film serving as a gate electrode.

The first mask film 13, to which a shape of the second mask film 14 as an upper layer is transferred, serves as a hard mask when the etching target film 12 as a lower layer is etched. The first mask film 13 may have a high selectivity as compared to the etching target film 12 when the etching target film 12 is etched. That is, a ratio of an etching rate of the etching target film 12 to an etching rate of the first mask film 13 may be high. For example, as the first mask film 13, it may be possible to use an inorganic film such as a SiN film and a SiON film. A thickness of the first mask film 13 may be set to be, for example, about 200 nm.

The second mask film 14, to which a resist pattern shape of the resist film 16 as an upper layer is transferred, serves as a mask when the first mask film 13 as a lower layer is etched. The second mask film 14 has a high selectivity as compared to the first mask film 13 when the first mask film 13 is etched. That is, a ratio of the etching rate of the first mask film 13 to an etching rate of the second mask film 14 is high. By way of example, as the second mask film 14, it may be possible to use an organic film made of a variety of organic materials such as amorphous carbon formed by chemical vapor deposition CVD, polyphenol formed by spin-on techniques or a photoresist such as a i-line resist. A thickness of the second mask film 14 may be set to be, for example, about 280 nm.

The anti-reflective coating 15 serves as an antireflection film when a photolithography process is performed on the resist film 16 formed on the anti-reflective coating 15. For example, as the anti-reflective coating 15, it is possible to use a film made of CₓH_{y}O_{z} referred to as an organic BARC. A thickness of the anti-reflective coating 15 may be set to be, for example, 80 nm.

The resist film 16 is formed on the wafer 10 on which the above-described films from the insulating film 11 to the anti-reflective coating 15 are layered. A pattern of the formed resist film 16 is exposed to lights and developed, so that the resist pattern having the line groups 16a and 16b formed of the resist film 16 is formed. As depicted in FIG. 7A, a resist pattern formed of the resist film 16 has lines of line widths CD and heights H. On the left of FIG. 7A, there is formed an area A1 (hereinafter, referred to as “dense area”) where the lines 16a are arranged at a relatively small distance D1 and on the right of FIG. 7A, there is formed an area A2 (hereinafter, referred to as “sparse area”) where the lines 16b are arranged at a relatively large distance D2 (larger than the distance D1). The line groups 16a and 16b serve as a mask when the anti-reflective coating 15 and the second mask film 14 are etched. As the resist film 16, it may be possible to use, for example, an ArF resist. Further, a thickness of the resist film 16 may be set to be, for example, about 170 nm.

Herein, a line width CD is a width of a line in a direction orthogonal to an extended direction of the line.

The line in the dense area A1 serves as a first line of the present disclosure. Further, a line in the sparse area A2 serves as a second line of the present disclosure.

After the resist pattern forming process (step S11) and before the anti-reflective coating etching process (step S12), a slimming process or a trimming process may be performed, so that a line width adjusting process for reducing line widths CD of the line groups 16a and 16b of the resist film 16 may be performed. If the line width adjusting process is performed, a line width CD indicates a width of the line after the line width adjusting process.

Then, the anti-reflective coating etching process (step S12) is performed. In the anti-reflective coating etching process (step S12), plasma is irradiated onto the wafer 10 and the anti-reflective coating 15 is etched by the irradiated plasma by using the line groups 16a and 16b formed of the resist film 16 as a mask. FIG. 7B shows a status of a wafer in the anti-reflective coating etching process (step S12).

In response to a control signal from the apparatus controller 190, the upper electrode driving unit 200 is moved in a vertical direction and a distance between the susceptor 105 and the upper electrode 120 is set to be a preset gap G. Thereafter, in response to a control signal from the apparatus controller 190, a predetermined supply amount FLI of a processing gas is supplied to the central area of the wafer W supported on the susceptor 105 in the chamber 102 from the gas supply apparatus 150 via the first branch line 172 and the first buffer room 143a of the shower head 140. Further, in response to a control signal from the apparatus controller 190, a predetermined supply amount FLO of a processing gas is supplied to the outer peripheral area of the wafer W supported on the susceptor 105 in the chamber 102 from the gas supply apparatus 150 via the second branch line 173 and the second buffer room 143b of the shower head 140. Then, in response to a control signal from the apparatus controller 190, a first high frequency power is applied from the first high frequency power supply 114 and a second high frequency power is applied from the second high frequency power supply 116. The processing gas introduced into the chamber 102 is excited into plasma by the high frequency power applied into the chamber 102 from the first high frequency power supply 114 and the second high frequency power supply 116 which are connected with the susceptor 105.

The excited plasma contains ions, electrons, and radicals. The ions are attracted toward the wafer 10 supported on the susceptor 105 by a bias voltage generated between the upper electrode 120 and the susceptor 105 and react with the surface of the wafer 10, so that the wafer 10 is etched. Meanwhile, the radicals are not attracted by a bias potential but diffuse to the surface of the wafer 10 and react with the surface of the wafer 10, so that the wafer 10 is etched. Consequently, the anti-reflective coating 15 is etched using the line groups 16a and 16b formed of the resist film 16 as a mask.

Further, the ions serve as charged particles of the present disclosure and the radicals serve as neutral particles of the present disclosure.

In the anti-reflective coating etching process (step S12), as the processing gas, it may be possible to use a mixed gas of a CF-based gas such as CF₄, C₄F₈, CHF₃, CH₃F, and CH₂F₂ with an Ar gas, or the mixed gas further including an oxygen gas if necessary.

Subsequently, the second mask film etching process (steps S13) is performed. In the second mask film etching process (steps S13), the second mask film 14 is etched by plasma irradiated to the wafer 10 using line groups 15a and 15b formed of the resist film 16 and the anti-reflective coating 15 as a mask, so that line groups 14a and 14b including the second mask film 14 are formed. FIG. 7C shows a wafer state in the second mask film etching process (step S13).

In the second mask film etching process (step S13), a temperature distribution in the surface of the wafer 10 supported on the susceptor 105 is adjusted and a distribution of a supply amount of the processing gas supplied to the wafer 10 in the surface of the wafer 10 is adjusted. By these adjustments, a distribution of a reaction amount between the radicals of the plasma in the surface of the wafer 10 and the surface of the wafer 10 is controlled. By controlling the distribution of the reaction amounts it is possible to control a distribution of line widths CD of the line groups 14a and 14b in the surface of the wafer 10.

In response to a control signal from the apparatus controller 190 to the temperature distribution adjusting unit 106, temperatures of the central and outer peripheral thermometers 106e and 106f are adjusted to predetermined temperatures TI and TO, respectively. Further, in response to the control signal from the apparatus controller 190 to the temperature distribution adjusting unit 106, the central heater 106a and the outer peripheral heater 106b are controlled independently. Consequently, it is possible to set the temperature TI at the central area of the wafer 10 to be different from the temperature TO at the outer peripheral area of the wafer 10, and, thus, the temperature distribution in the surface of the wafer 10 can be adjusted.

Further, in response to a control signal from the apparatus controller 190 to the supply amount distribution adjusting unit 130, a gas from the first gas box 161 is supplied to the first buffer room 143a and the second buffer room 143b of the shower head 140 via each of the first branch line 172 and the second branch line 173. Since the flow rates in the first branch line 172 and the second branch line 173 are adjusted by the pressure adjusting units 174 and 175, the flow rate FLI of the processing gas supplied to the central area of the wafer 10 can be set to be different from the flow rate FLO of the processing gas supplied to the outer peripheral area of the wafer 10. Consequently, it is possible to adjust the distribution of supply amounts of the processing gas in the surface of the wafer 10.

As described above, by adjusting the temperature distribution and the distribution of supply amounts of the processing gas in the surface of the wafer 10, it is possible to control the distribution of line widths CD of the line groups 14a and 14b formed of the second mask film 14 in the surface of the wafer 10.

In the second mask film etching process (step S13), in response to a control signal from the apparatus controller 190 to the upper electrode driving unit 200, a gap G between the wafer 10 supported on the susceptor 105 and the upper electrode 120 facing the wafer 10 is adjusted. By adjusting the gap G, it is possible to control a distribution of irradiation amounts of ions in the surface of the wafer 10 and a distribution of etching rates ER in a longitudinal direction (depth direction). Further, by controlling the distribution of etching rates ER in the longitudinal direction (depth direction), it is possible to control a distribution of heights H of the line groups 14a and 14b in the surface of the wafer 10.

In the second mask film etching process (step S13), it may be possible to use an oxygen (O₂) gas as the processing gas.

Thereafter, the first mask film etching process (step S14) is performed. In the first mask film etching process (step S14), the first mask film 13 is etched by plasma irradiated to the wafer 10 using the line groups 14a and 14b formed of the second mask film 14 as a mask, so that line groups 13a and 13b including the first mask film 13 are formed. FIG. 7D shows a status of a wafer in the first mask film etching process (step S14).

In the first mask film etching process (step S14), a temperature distribution in the surface of the wafer 10 supported on the susceptor 105 is adjusted and a distribution of supply amounts of the processing gas supplied to the wafer 10 in the surface of the wafer 10 is adjusted. By these adjustments, a distribution of reaction amounts between the radicals of the plasma in the surface of the wafer 10 and the surface of the wafer 10 is controlled. By controlling the distribution of reaction amounts, it is possible to control a distribution of line widths CD of the line groups 13a and 13b in the surface of the wafer 10.

Further, in the first mask film etching process (step S14), in response to a control signal from the apparatus controller 190 to the upper electrode driving unit 200, a gap G between the wafer 10 supported on the susceptor 105 and the upper electrode 120 provided so as to face the wafer 10 is adjusted. By adjusting the gap G, it is possible to control a distribution of irradiation amounts of ions in the surface of the wafer 10 and a distribution of etching rates ER in a longitudinal direction (depth direction). Further, by controlling the distribution of etching rates ER in the longitudinal direction (depth direction), it is possible to control a distribution of heights H of the line groups 13a and 13b in the surface of the wafer 10.

In the first mask film etching process (step S14), as the processing gas, it may be possible to use a mixed gas of a CF-based gas such as CF₄, C₄F₈, CHF₃, CH₃F, and CH₂F₂ with an Ar gas, or the mixed gas further including an oxygen (O₂) gas if necessary.

There may be a following relationship between the second mask film etching process (step S13) and the first mask film etching process (step S14). That is, temperature dependency of a reaction amount between the radicals and a surface of the first mask film 13 in the first mask film etching process (step S14) may be greater than temperature dependency of a reaction amount between the radicals and a surface of the second mask film 14 in the second mask film etching process (step S13). That is because, as described below, if the relationship is satisfied, it is impossible to independently control a distribution of line widths CD of the line groups and a distribution of heights H of the line groups in the surface of the wafer 10 in the conventional method.

Then, the etching target film etching process (step S15) is performed. In the etching target film etching process (step S15), the etching target film 12 is etched by plasma irradiated to the wafer 10 using the line groups 13a and 13b formed of the first mask film 13 as a mask, so that line groups 12a and 12b including the etching target film 12 are formed. FIG. 7E shows a status of a wafer in the etching target film etching process (step S15).

In the etching target film etching process (step S15), such control as performed in the first mask film etching process (step S14) may be performed. That is, by adjusting the temperature distribution and the distribution of supply amounts of the processing gas in the surface of the wafer 10, it is possible to control a distribution of line widths CD of the line groups 12a and 12b in the surface of the wafer 10, and by adjusting the gap G between the upper electrode 120 and the wafer 10, it is possible to control a distribution of heights H of the line groups 12a and 12b in the surface of the wafer 10.

In the etching target film etching process (step S15), as the processing gas, it may be possible to use a mixed gas of a CF-based gas such as CF₄, C₄F₈, CHF₃, CH₃F, and CH₂F₂ with an Ar gas, or the mixed gas further including an oxygen (O₂) gas if necessary.

Hereinafter, there will be explained a case where a distribution of line widths CD of lines and a distribution of heights H of the lines in a surface of a wafer are independently controlled and an etching process can be performed with high uniformity in cross sectional shapes of lines when the etching process is performed on the wafer using the plasma etching method in accordance with the present embodiment.

As described above, the plasma of the processing gas contains the ions and the radicals. Since the ions are accelerated by the bias voltage generated between the upper electrode 120 and the susceptor 105 and irradiated to the wafer, an anisotropic etching process is mainly performed on the wafer. Therefore, the lines to be formed are mainly etched in a longitudinal direction (depth direction). Meanwhile, the radicals are not accelerated by the bias voltage, and, thus, an isotropic etching process is mainly performed on the wafer. Therefore, the lines to be formed are mainly etched in a width direction. Further, a reaction product generated by a reaction between a surface of the wafer and the plasma may adhere to the lines again. Here, a line width CD of the lines may vary depending on an adhesion coefficient which indicates a probability that the reaction product adheres to the line again. Since the adhesion coefficient depends on a temperature of the wafer, the line width CD of the lines may vary depending on the temperature of the wafer.

As described above, in the plasma etching process, an etching condition (parameter) controlling an etching rate ER in a vertical direction (longitudinal direction) is different from an etching condition (parameter) controlling a line width CD of the lines in the surface of the wafer.

When plasma is irradiated to the wafer, the parameter controlling the etching rate ER in the longitudinal direction includes an amount of ions (ion flux) approximately vertically incident to a surface of the wafer per unit time; energy of ions; and an adsorption amount of radicals adsorbed to the surface of the wafer. When the radicals are supplied sufficiently, the most dominant parameter in controlling the etching rate ER in the longitudinal direction is the ion flux. In order to control a distribution of line widths CD of lines formed by an etching process in the surface of the wafer, it is necessary to independently control a distribution of the ion flux and a distribution of reaction amounts of the radicals.

Herein, a method of controlling a distribution of an ion flux in the surface of the wafer may include the following three methods: a method of adjusting a distribution of a magnetic field by using a permanent magnet or an electromagnet; a method of adjusting a distribution of an electric field by dividing an electrode and adjusting impedance; and a method of forming protrusions or recesses in the upper electrode or adjusting a distance (gap) between the upper electrode and the lower electrode.

Among these three methods of controlling the distribution of the ion flux, in accordance with the method of adjusting the distribution of the magnetic field, the distribution of the ion flux cannot be controlled stably. Especially, a magnetic field exists near the wafer, and, thus, arcing may occur easily. Further, in accordance with the method of adjusting the distribution of the electric field by dividing an electrode and adjusting impedance, the distribution of the ion flux cannot be made substantially uniform.

Meanwhile, in accordance with the method of adjusting the gap G, the ion flux may be adjusted in a wide range. By adjusting the ion flux, it is possible to control the distribution of etching rates ER in the longitudinal direction in the surface of the wafer.

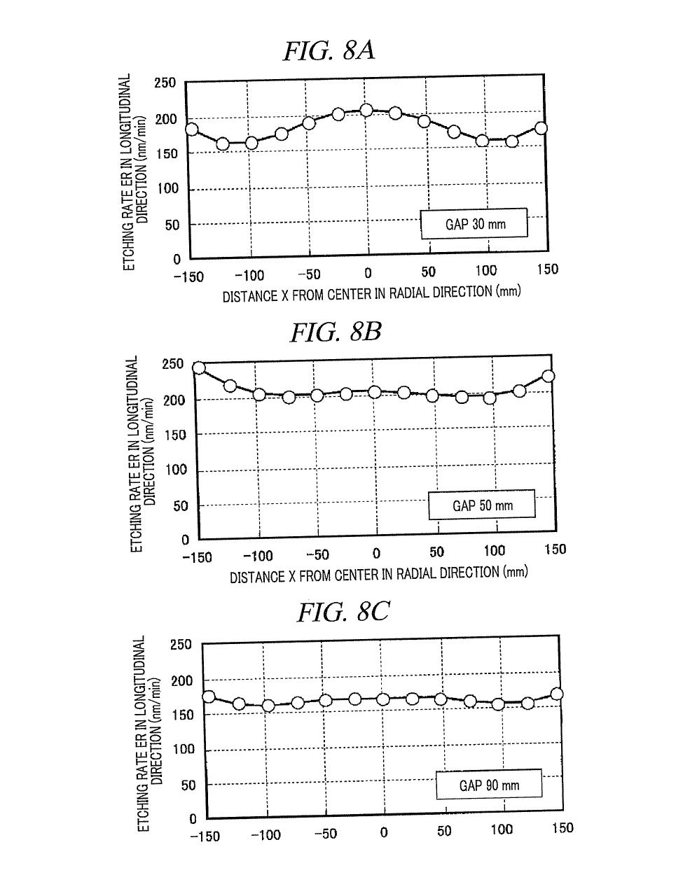

Hereinafter, referring to FIGS. 8A to 8C, gap dependency of an etching rate ER in a longitudinal direction will be explained. FIGS. 8A to 8C are graphs showing distributions of etching rates ER in a longitudinal direction in a surface of a wafer when a gap G is adjusted. The gaps G in FIGS. 8A, 8B, and 8C are 30 mm, 50 mm, and 90 mm, respectively. In FIGS. 8A to 8C, a horizontal axis represents a distance X from a center in a radial direction and a vertical axis represents an etching rate ER in a longitudinal direction. Further, a wafer of 300 mmØ is used.

As depicted in FIG. 8A, when a gap G is about 30 mm, an etching rate ER in a longitudinal direction is maximized at a central area of the wafer and gradually decreased toward an outer peripheral area of the wafer and after reaching a minimum value, the etching rate ER is slightly increased at the outer peripheral area. Thus, a distribution of etching rates ER is not uniform in a surface of the wafer. In this case, an average of the etching rates ER in the longitudinal direction is about 178.4 nm/min and a deviation is about 14.9%.

Meanwhile, as depicted in FIG. 8B, when a gap G is about 50 mm, an etching rate ER becomes more uniform in the surface of the wafer although an etching rate ER in a longitudinal direction is increased at the outer peripheral area of the wafer as compared to that in the central area of the wafer. In this case, an average of the etching rates ER in the longitudinal direction is about 208.3 nm/min and a deviation is about 12.6%.

Further, as depicted in FIG. 8C, when a gap G is about 90 mm, an etching rate ER in a longitudinal direction becomes much more uniform in the surface of the wafer. In this case, an average of the etching rates ER in the longitudinal direction is about 164.5 nm/min and a deviation is about 7.3%.

As described above, by adjusting a gap G, it is possible to control a distribution of ion flux.

When the plasma is irradiated to the wafer, the ions contained in the plasma are substantially vertically incident to the surface of the wafer and scarcely irradiated to sidewalls of the lines. Therefore, parameters controlling line widths CD of lines to be formed may include an amount of a polymer film formed on a surface of the sidewall of the line due to adhesion of the radicals to the sidewall and an etching amount of the surface of the sidewall of the line due to a reaction between the radicals and the sidewall of the line.

Herein, a method of controlling a reaction amount of the radicals in the surface of the wafer may include the following three methods: a method of adjusting a distribution of a supply amount of a processing gas supplied to generate the radicals; a method of adjusting a distribution of a composition ratio of the processing gas supplied as a mixed gas; and a method of adjusting a temperature distribution in the surface of the wafer in order to adjust a reaction rate.

Among these three methods of controlling the distribution of reaction amounts of the radicals, in accordance with the method of adjusting the distribution of the supply amount of the processing gas and the method of adjusting the distribution of the composition ratio of the processing gas, it is impossible to locally adjust the supply amount and the composition ratio of the processing gas in the surface of the wafer. For this reason, it is also impossible to locally adjust the distribution of the reaction amount of the radicals.

Meanwhile, in accordance with the method of adjusting the temperature distribution of the wafer, even if various processing gases and various radicals are used, it is possible to locally adjust the distribution of reaction amounts of the radicals. Thus, it is possible to locally control the distribution of line widths CD of the lines in the surface of the wafer.

To be specific, referring to Table 1, there will be explained a method of independently controlling a distribution of an ion flux and a distribution of a reaction amount of radicals by using the method of adjusting the gap G and the method of adjusting the temperature distribution of the wafer. Herein, as described below, the gap G and the temperature distribution of the wafer are adjusted under conditions (A) and (B), and a deviation of line widths CD in the surface of the wafer is calculated.

### (A) Second Mask Film Etching Process (Step S13)

Material of second mask film: naphthalene (or polystyrene)

Thickness of second mask film: 280 nm

Internal pressure of film forming apparatus: 20 mTorr

High frequency power (40 mHz/13 MHz): 500/0 W

Potential of upper electrode: 0 V

Flow rate of processing gas: O₂=750 sccm

Processing time: 60 seconds

### (B) First Mask Film Etching Process (Step S14)

Material of first mask film: silicon nitride (SiN)

Thickness of first mask film: 280 nm

Internal pressure of film forming apparatus: 75 mTorr

High frequency power (40 mHz/13 MHz): 500/0 W

Potential of upper electrode: 300 V

Flow rate of processing gas: CF₃/CF₄/Ar/O₂≦125/225/600/60 sccm (here, CH₂F₂ of about 20 sccm may be added to outer peripheral area)

Processing time: 60 seconds

In the conditions (A) and (B), a flow rate of the processing gas is used to adjust a supply amount of the processing gas, for example. However, it may be also possible to change a supply time of the processing gas by opening/closing a valve so as to adjust the supply amount of the processing gas without changing the flow rate of the processing gas.

Table 1 shows a deviation CD1σ of line widths in a dense area A1 when a gap G, a temperature TI at a central area of the wafer, and a temperature TO at an outer peripheral area of the wafer are adjusted. Further, Table 1 shows an example where a ratio between a flow rate FLI of the processing gas at the central area and a flow rate FLO of the processing gas at the outer peripheral area is optimized in advance to 50:50.

TABLE 1

| Gap G (mm) | 30 | 50 | 90 | 50 |
|---|---|---|---|---|
| Central area | 40 | 40 | 40 | 50 |
| temperature TI | | | | |
| (° C.) | | | | |
| Outer peripheral | 40 | 40 | 40 | 40 |
| area temperature TO | | | | |
| (° C.) | | | | |
| Flow rate ratio | 50:50 | 50:50 | 50:50 | 50:50 |
| between central | | | | |
| flow rate FLI and | | | | |
| outer peripheral | | | | |
| flow rate FLO | | | | |
| Deviation CD1σ (nm) | 7.5 | 3.8 | 1.9 | 1.5 |
| of line width CD at | | | | |
| dense area A1 | | | | |
| Deviation CD2σ (nm) | 36.5 | 7.2 | 7.7 | 2.9 |
| of line widths CD | | | | |
| at sparse area A2 | | | | |

As shown in Table 1, under the condition that the gap G is about 30 mm, the temperature TI at the central area is about 40° C., and the temperature TO at the outer peripheral area is about 40° C., the deviation CD1σ becomes as great as about 7.5 nm. Further, the deviation CD1σ is decreased to about 3.8 nm and about 1.9 nm by adjusting the gap G to about 50 mm and about 90 mm, respectively, without changing the condition that the temperature TI at the central area is about 40° C. and the temperature TO at the outer peripheral area is about 40° C.

Furthermore, by adjusting the temperature TI at the central area and the temperature TO at the outer peripheral area as well as the gap G, the deviation CD1σ can be decreased to about 1.5 nm under the condition that the gap G is about 50 mm, the temperature TI at the central area is about 50° C., and the temperature TO at the outer peripheral area is about 40° C.

That is, the present inventors have found that it is desirable to use the method of adjusting the gap G and the method of adjusting the temperature distribution of the wafer together in order to independently control the distribution of ion flux and the distribution of reaction amount of the radicals with low cost and high effect.

The line width CD of the line formed by an etching process may vary depending on a gap of adjacent lines (pattern gap) in addition to the adhesion coefficient. Therefore, the line width CD of the line formed on the wafer may vary depending on the temperature of the wafer and the pattern gap.

However, as described above, if there are areas having different pattern gaps in the surface of the wafer, it is difficult to independently control a line width CD of a line in the dense area A1 and a line width CD of a line in the sparse area A2 by adjusting only the temperature of the wafer. In this case, it may be possible to independently control the line widths CD of the lines in the dense area A1 and the sparse area A2 by adjusting the supply amount or composition ratio of the processing gas.

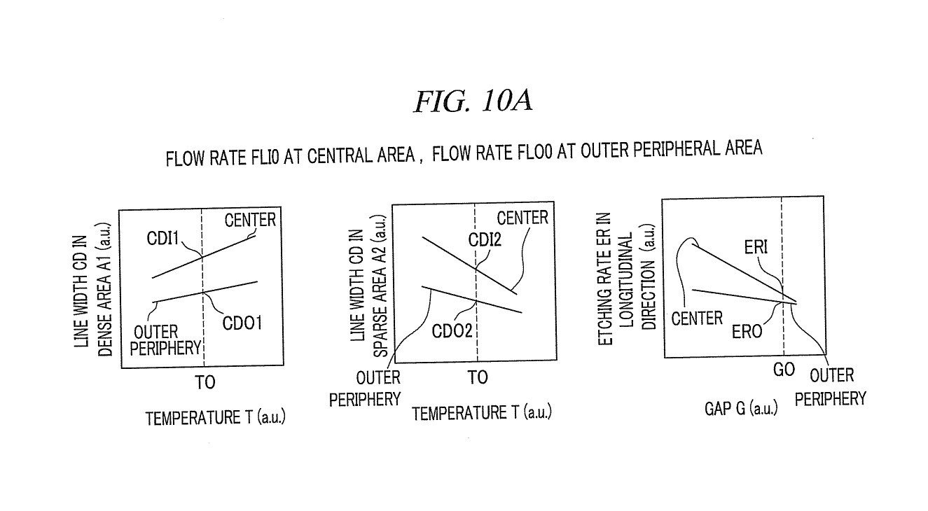

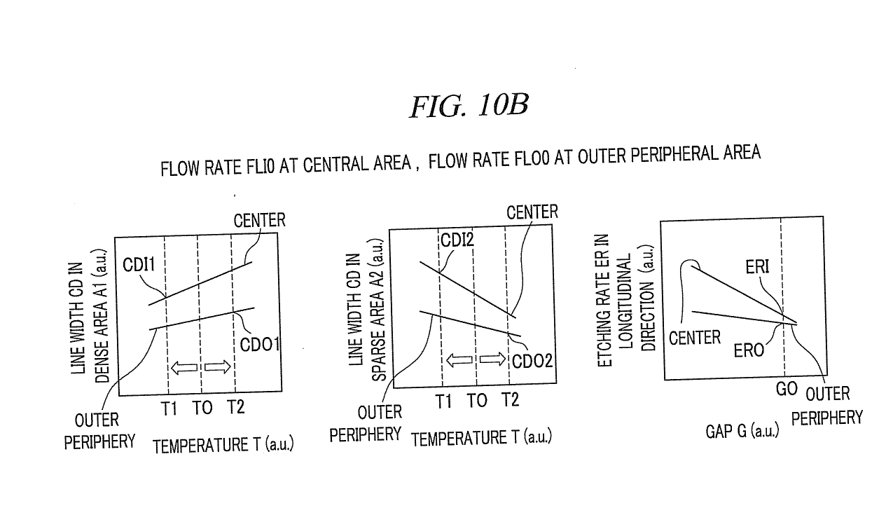

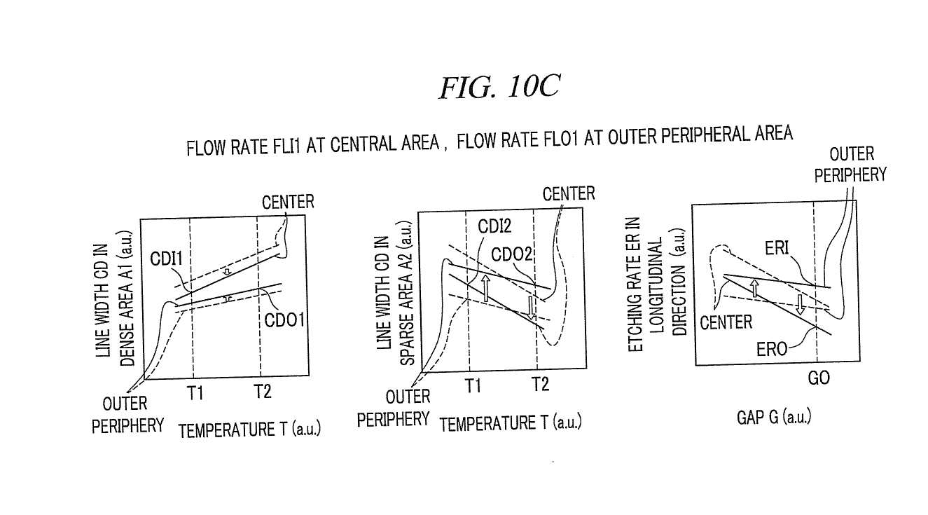

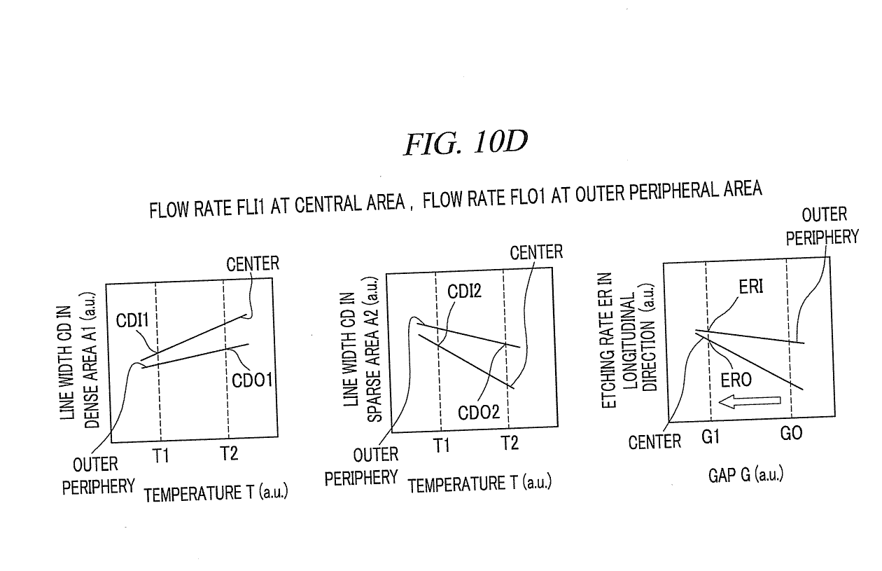

Further, Table 1 shows the deviation CD2σ of the line widths in the sparse area A2. As described above, the ratio between the flow rate FLI of the processing gas at the central area and the flow rate FLO of the processing gas at the outer peripheral area is optimized in advance to 50:50. For this reason, by adjusting the gap G, the temperature TI at the central area, and the temperature TO at the outer each of FIGS. 10A to 10D, the temperature dependency of line widths CD in the dense area A1, the temperature dependency of line widths CD in the sparse area A2 and the gap dependency of the etching rates ER in the longitudinal direction are shown in sequence from the left.

Referring to FIGS. 10A to 10D, there will be explained an example where in the first mask film etching process (step S14), it is possible to independently control the distribution of line widths CD and heights H of the line groups in the surface of the wafer and possible to perform an etching process with high uniformity in cross sectional shapes of the line groups.

FIG. 10A shows each dependency before a temperature distribution, a distribution of a supply amount, and a gap G are adjusted. In FIG. 10A, a flow rate FLI at the central area is set to be FLI0 and a flow rate FLO at the outer peripheral area is set to be FLO0. FIG. 10A shows an example where line widths CD both in the dense area A1 and in the sparse area A2 have different temperature dependency at the central area and the outer peripheral area of the wafer. Further, in the example shown in FIG. 10A, the temperature dependency of the line widths CD in the dense area A1 has a tendency opposite to a tendency of the temperature dependency of the line widths CD in the sparse area A2. Furthermore, in the example shown in FIG. 10A, etching rates ER in the longitudinal direction have different gap dependency at the central area and the outer peripheral area of the wafer. Here, the gap G is set to be G0 where a difference between the etching rates ER in the longitudinal direction at the central area and the outer peripheral area is small.

In the example shown in FIG. 10A, when the temperature TI at the central area of the wafer and the temperature TO at the outer peripheral area of the wafer are set to be same as a temperature TO, a line width CDI1 at the central area in the dense area A1 cannot be the same as a line width CDO1 at the outer peripheral area in the dense area A1. Further, a line width CDI12 at the central area in the sparse area A2 cannot be the same as a line width CDO2 at the outer peripheral area in the sparse area A2.

FIG. 10B shows each dependency after the temperature distribution is adjusted. As depicted in FIG. 10B, the temperature TI at the central area is set to be T1 lower than T0, and the temperature TO at the outer peripheral area is set to be T2 higher than T0. In this way, by adjusting the temperature distribution in the surface of the wafer, a difference between the line width CDI1 at the central area in the dense area A1 and the line width CDO1 at the outer peripheral area in the dense area A1 can be further reduced. However, since the temperature dependency of the line widths CD in the dense area A1 has a tendency opposite to a tendency of the temperature dependency of the line widths CD in the sparse area A2, a difference between the line width CDI2 at the central area in the sparse area A2 and the line width CDO2 at the outer peripheral area in the sparse area A2 may not be reduced.

FIG. 10C shows each dependency after the distribution of the supply amount of the processing gas is adjusted. As depicted in FIG. 10C, the flow rate at the central area is set to be FLI1 lower than FLI0 and the flow rate at the outer peripheral area is set to be FLO1 higher than FLO0. In this way, by adjusting the distribution of the gas supply amount in the surface of the wafer, the reaction amount of the radicals at the central area is decreased in the dense area A1 and in the sparse area A2, and, thus, a straight line that represents the temperature dependency of the line width CD moves downward. Meanwhile, the reaction amount of the radicals at the outer peripheral area is increased, and, thus, a straight line that represents the temperature dependency of the line width CD moves upward.

Further, the lines 13b in the sparse area A2 are more likely to be in contact and react with the radicals than the lines 13a in the dense area A1. For this reason, when the gas supply amount is changed, the line widths CD of the lines 13b in the sparse area A2 may be greatly changed as compared to the line widths CD of the lines 13a in the dense area A1. That is, the gas supply amount dependency of the reaction amount between the lines 13a in the dense area A1 and the radicals may be less than the gas supply amount dependency of the reaction amount between the lines 13b in the sparse area A2 and the radicals.

Therefore, by adjusting the distribution of the gas supply amount, the line widths CD can be greatly changed in the sparse area A2 as compared to those in the dense area A1. Further, as depicted in FIG. 10C, the line width CDI1 at the central area in the dense area A1 may be set to be substantially the same as the line width CDO1 at the outer peripheral area in the dense area A1, and the line width CDI12 at the central area in the sparse area A2 may be set to be substantially the same as the line width CDO2 at the outer peripheral area in the sparse area A2.

However, if the gas supply amount is changed, an ion flux may be changed. Thus, as depicted in FIG. 10C, an etching rate ER in the longitudinal direction may be also changed. The ion flux at the central area is decreased and the ion flux at the outer peripheral area is increased. Thus, when the gap is G0, a difference between an etching rate ERI in the longitudinal direction at the central area and an etching rate ERO in the longitudinal direction at the outer peripheral area becomes increased as compared to a difference in the case before the temperature distribution and the gas supply amount in the wafer surface are adjusted.

In the first mask film etching process (step S14), by adjusting the gap G, the difference between the etching rate ERI in the longitudinal direction at the central area and the etching rate ERO in the longitudinal direction at the outer peripheral area may be decreased.

FIG. 10D shows each dependency after the gap G is adjusted. In the example shown in FIG. 10D, the gap is set to be G1 smaller than G0. Thus, the difference between the etching rate ERI in the longitudinal direction at the central area and the etching rate ERO in the longitudinal direction at the outer peripheral area can be decreased. Therefore, after the distribution of the reaction amount of the radicals in the wafer surface is adjusted, the etching rate ER in the longitudinal direction in the wafer surface may be adjusted.

As described above, in the first mask film etching process (step S14), by adjusting the gap G in addition to controlling the temperature distribution and the supply amount or composition ratio of the processing gas, it is possible to independently control the distribution of line widths CD of the line groups and the distribution of etching rates ER in the longitudinal direction. Consequently, the line widths CD and the heights H in the surface of the wafer can be uniformed and cross sections of the line groups may also be uniformed.

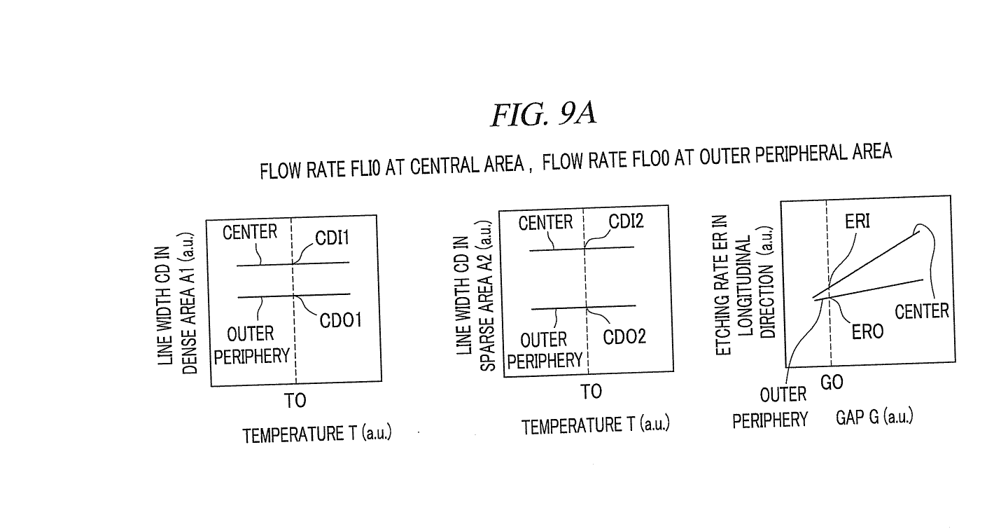

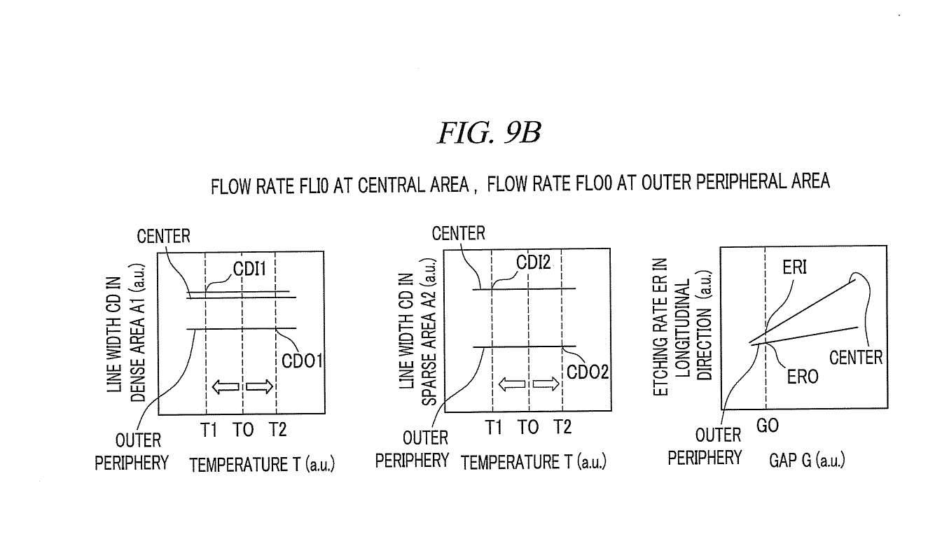

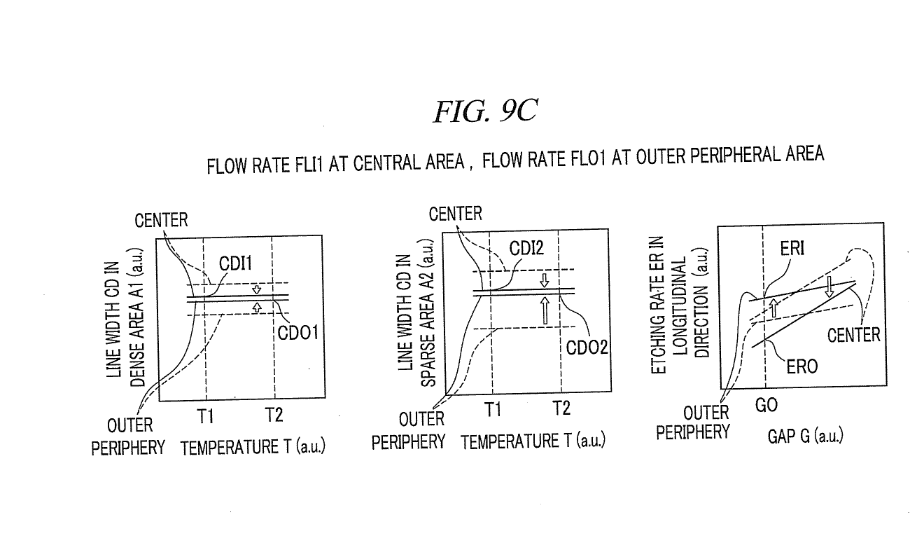

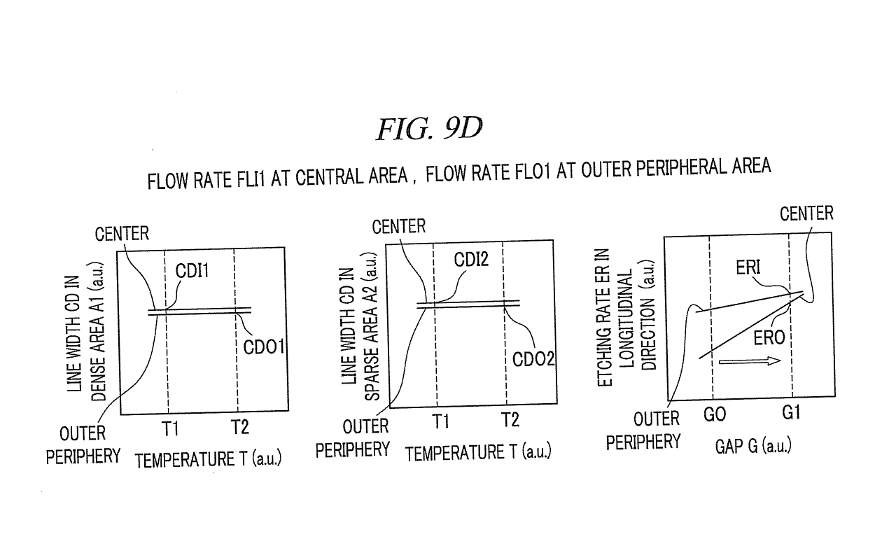

Hereinafter, there will be explained an example where it is possible to independently control the distribution of line widths CD and heights H of line groups in a surface of a wafer and to perform an etching process with high uniformity in cross sectional shapes of lines in the second mask film etching process (step S13) shown in FIGS. 9A to 9D.

FIG. 9A shows each dependency before a temperature distribution, a distribution of a supply amount, and a gap G are adjusted. In FIG. 9A, a flow rate FLI at a central area is set to be FLI0 and a flow rate FLO at an outer peripheral area is set to be FLO0. FIG. 9A shows an example where line widths CD both in a dense area A1 and in a sparse area A2 have little temperature dependency at the central area and the outer peripheral area of the wafer. Further, in the example shown in FIG. 9A, etching rates ER in the longitudinal direction have different gap dependency at the central area and the outer peripheral area of the wafer. Here, the gap G is set to be G0 where a difference between the etching rates ER in the longitudinal direction at the central area and the outer peripheral area is small.

That is, temperature dependency of a reaction amount between radicals and the surface of the second mask film 14 in the second mask film etching process (step S13) may be smaller than temperature dependency of a reaction amount between radicals and the surface of the first mask film 13 in the first mask film etching process (step S14). The radicals in the second mask film etching process (step S13) serve as first neutral particles of the present disclosure. Further, the radicals in the first mask film etching process (step S14) serve as second neutral particles of the present disclosure.

In the example shown in FIG. 9A, when a temperature TI at the central area of the wafer and a temperature TO at the outer peripheral area of the wafer are set to be same as a temperature T0, a line width CDI1 at the central area in the dense area A1 cannot be the same as a line width CDO1 at the outer peripheral area in the dense area A1. Further, a line width CD12 at the central area in the sparse area A2 cannot be the same as a line width CDO2 at the outer peripheral area in the sparse area A2.

The line widths CD have little temperature dependency when the processing gas has a small reaction rate between radicals and sidewalls of lines or the radicals adhering to the sidewalls of the lines has a low adhesion coefficient. As described above, in the second mask film etching process (step S13), an oxygen (O₂) gas is used as the processing gas, but oxygen radicals (O*) contained in plasma may have a low reaction coefficient and a low adhesion coefficient.

FIG. 9B shows each dependency after the temperature dependency is changed. As depicted in FIG. 9B, originally, the line widths CD have little temperature dependency both in the dense area A1 and the sparse area A2. Therefore, even if the temperature TI at the central area is set to be T1 lower than T0 and the temperature TO at the outer peripheral area is set to be T2 higher than T0, a difference between the line width CDI1 at the central area in the dense area A1 and the line width CDO1 at the outer peripheral area in the dense area A1 may not be decreased. Further, a difference between the line width CDI2 at the central area in the sparse area A2 and the line width CDO2 at the outer peripheral area in the sparse area A2 may not be decreased.

FIG. 9C shows each dependency after the distribution of the supply amount of the processing gas is adjusted. As depicted in FIG. 9C, the flow rate at the central area is set to be FLI1 lower than FLI0 and the flow rate at the outer peripheral area is set to be FLO1 higher than FLO0. In this way, by adjusting the distribution of the gas supply amount in the surface of the wafer, the reaction amount of the radicals at the central area is decreased in the dense area A1 and in the sparse area A2, and, thus, a straight line that represents the temperature dependency of the line width CD moves downward. Meanwhile, the reaction amount of the radicals at the outer peripheral area is increased, and, thus, a straight line that represents the temperature dependency of the line width CD moves upward.

In the same manner as the first mask film etching process (step S14), by way of example, the lines 14b in the sparse area A2 are more likely to be in contact and react with the radicals than the lines 14a in the dense area A1. For this reason, when the gas supply amount is changed, the line widths CD of the lines 14b in the sparse area A2 may be greatly changed as compared to the line widths CD of the lines 14a in the dense area A1. That is, the gas supply amount dependency of the reaction amount between the lines 14a in the dense area A1 and the radicals may be less than the gas supply amount dependency of the reaction amount between the lines 14b in the sparse area A2 and the radicals.

Therefore, by adjusting the distribution of the gas supply amount, the line widths CD can be greatly changed in the sparse area A2 as compared to those in the dense area A1. Further, as depicted in FIG. 9C, the line width CDI1 at the central area in the dense area A1 may be set to be substantially the same as the line width CDO1 at the outer peripheral area in the dense area A1, and the line width CDI12 at the central area in the sparse area A2 may be set to be substantially the same as the line width CDO2 at the outer peripheral area in the sparse area A2.

However, in the same manner as the example shown in FIGS. 10A to 10D, if the gas supply amount is changed, an ion flux as well as the supply amount of the radicals may be changed. Thus, as depicted in FIG. 9C, an etching rate ER in the longitudinal direction may be changed. The ion flux at the central area is decreased and the ion flux at the outer peripheral area is increased. Thus, when the gap is G0, a difference between an etching rate ERI in the longitudinal direction at the central area and an etching rate ERO in the longitudinal direction at the outer peripheral area becomes increased as compared to a difference in the case before the temperature distribution and the gas supply amount in the wafer surface are adjusted.

In the second mask film etching process (step S13), by adjusting the gap G, the difference between the etching rate ERI in the longitudinal direction at the central area and the etching rate ERO in the longitudinal direction at the outer peripheral area may be decreased.

FIG. 9D shows each dependency after the gap G is adjusted. In the example shown in FIG. 9D, the gap is set to be G1 smaller than G0. Thus, the difference between the etching rate ERI in the longitudinal direction at the central area and the etching rate ERO in the longitudinal direction at the outer peripheral area can be decreased. Therefore, after the distribution of the reaction amount of the radicals in the wafer surface is adjusted, the etching rate ER in the longitudinal direction in the wafer surface may be adjusted.

As described above, in the second mask film etching process (step S13), the processing gas having a low reaction rate or adhesion coefficient of the radicals is used, and, thus, even if the temperature of the wafer and the supply amount or composition ratio of the processing gas are adjusted, it is impossible to control the line widths CD of the lines. However, by adjusting the gap G in addition to controlling the temperature distribution and the supply amount or composition ratio of the processing gas, it is possible to independently control the distribution of line widths CD of the line groups and the distribution of etching rates ER in the longitudinal direction. Consequently, the line widths CD and the heights H in the surface of the wafer can be uniformed and uniform cross sectional shape can be achieved.

In the example described with reference to FIGS. 9A to 10D, for the simplicity of explanation, it has been explained that the temperature distribution in the wafer surface is first adjusted; the distribution of the gas supply amount in the wafer surface is then adjusted; and then the gap G is finally adjusted. However, the sequence of adjusting the temperature distribution, the distribution of gas supply amounts, and the gap G is not limited thereto, and their adjustments can be carried out in any sequence.

Further, it may be possible to prepare in advance data of line widths CD and etching rates ER in a longitudinal direction in the dense area A1 and the sparse area A2, which are obtained under respective conditions of the temperatures TI and TO at the central area and the outer peripheral area, the flow rates FLI and FLO at the central area and the outer peripheral area, and the gap G. In this case, each condition may be optimized such that the distributions of line widths CD and etching rates ER in the wafer surface can be uniformed based on the data prepared in advance. The optimization of each condition can be carried out by the apparatus controller 190.

Further, when selecting a mask film and a processing gas for etching the mask film, it is desirable to control a distribution of shapes of lines in the wafer surface while achieving selectivity in etching rates between an upper film and a lower film when the mask film is etched. Therefore, in accordance with the present embodiment, it may be possible to use a mask film including inorganic and organic films capable of increasing selectivity in etching rates for each processing gas when the processing gas is varied. Thus, it may be possible to transfer a shape of a resist pattern onto an etching target film with high accuracy and also possible to uniform a distribution of shapes of lines formed of the etching target film in the wafer surface.

The present embodiment has been explained for the example where the mask film is composed of the upper mask film including the organic film and the lower mask film including the inorganic film. However, the present embodiment can also be applied to a case where a mask film includes only a single film and in this case, it is also possible to uniform a distribution of shapes of lines formed of an etching target film in a wafer surface.

### Modification Example of First Embodiment

Hereinafter, a plasma etching method and a plasma etching apparatus in accordance with a modification example of the first embodiment will be explained.

The present modification example is different from the first embodiment in that when an organic film is etched, a processing gas having a high adhesion coefficient and having radicals of a high reaction rate is used in a second mask film etching process.

In the present modification example, the plasma etching apparatus explained with reference to FIGS. 1 to 5 may be used, as in the first embodiment. Further, as the first embodiment, a plasma etching method in accordance with the present modification example also includes a resist pattern forming process (step S11), an anti-reflective coating etching process (step S12), a second mask film etching process (step S13), a first mask film etching process (step S14), and an etching target film etching process (step S15) explained with reference to FIG. 6. Furthermore, a wafer state in each process is the same as illustrated in FIGS. 7A to 7E.

Meanwhile, in the present modification example, in the second mask film etching process (step S13), it may be possible to use a mixed gas including a nitrogen (N₂) gas/a hydrogen (H₂) gas instead of an oxygen (O₂) gas as a processing gas. When a temperature distribution, a distribution of a supply amount, and a gap G are adjusted in the second mask film etching process (step S13), example processing conditions other than the processing gas are as follows.

### (C) Second Mask Film Etching Process (Step S13)

Material of second mask film: naphthalene (or polystyrene)

Thickness of second mask film: 280 nm

Internal pressure of film forming apparatus: 100 mTorr

High frequency power (40 mHz/13 MHz): 700/0 W

Potential of upper electrode: 0 V

Flow rate of processing gas: N₂/H₂=160/480 sccm

Processing time: 60 seconds

When the second mask film 14 is etched by using the mixed gas including the nitrogen (N₂) gas/the hydrogen (H₂) gas, line widths CD may be observed to have temperature dependency and gas supply amount dependency and an etching rate ER in a longitudinal direction may have gap dependency in the same way as described in the first embodiment in FIGS. 10A to 10D. Therefore, the temperature distribution, the distribution of the supply amount, and the gap G can be adjusted in the same manner as the first mask film etching process (step S14) in the first embodiment.

That is, as depicted in FIG. 10A, a line width CD has different temperature dependency at a central area and an outer peripheral area of a wafer. For this reason, as depicted in FIG. 10B, by adjusting only the temperature distribution in the wafer surface, it is possible to decrease a difference between a line width CDI1 at the central area in a dense area A1 and a line width CDO1 at the outer peripheral area in the dense area A1 but it is impossible to decrease a difference between a line width CDI2 at the central area in a sparse area A2 and a line width CDO2 at the outer peripheral area in the sparse area A2. Further, as depicted in FIG. 10C, by adjusting flow rates FLI and FLO of the processing gas at the central area and the outer peripheral area, it is possible to make the line width CDI1 at the central area in the dense area A1 substantially the same as the line width CDO1 at the outer peripheral area in the dense area A1 and also possible to make the line width CDI2 at the central area in the sparse area A2 substantially the same as the line width CDO2 at the outer peripheral area in the sparse area A2. Here, since the ion flux is also changed, by adjusting the gap G, it is possible to decrease a difference between the etching rate ERI in the longitudinal direction at the central area and the etching rate ERO in the longitudinal direction at the outer peripheral area as depicted in FIG. 10D.

Therefore, in accordance with the present embodiment, it may be possible to use a mask film including inorganic and organic films capable of increasing selectivity in etching rates for each processing gas when the processing gas is varied. Thus, it may be possible to transfer a shape of a resist pattern onto an etching target film with high accuracy and also possible to uniform a distribution of shapes of lines formed of the etching target film in the wafer surface.

Further, the present modification example can also be applied to a case where a mask film is composed of a film including either an organic film or an inorganic film and in such a case, it is possible to uniform a distribution of shapes of lines formed of an etching target film in a wafer surface.

### Second Embodiment

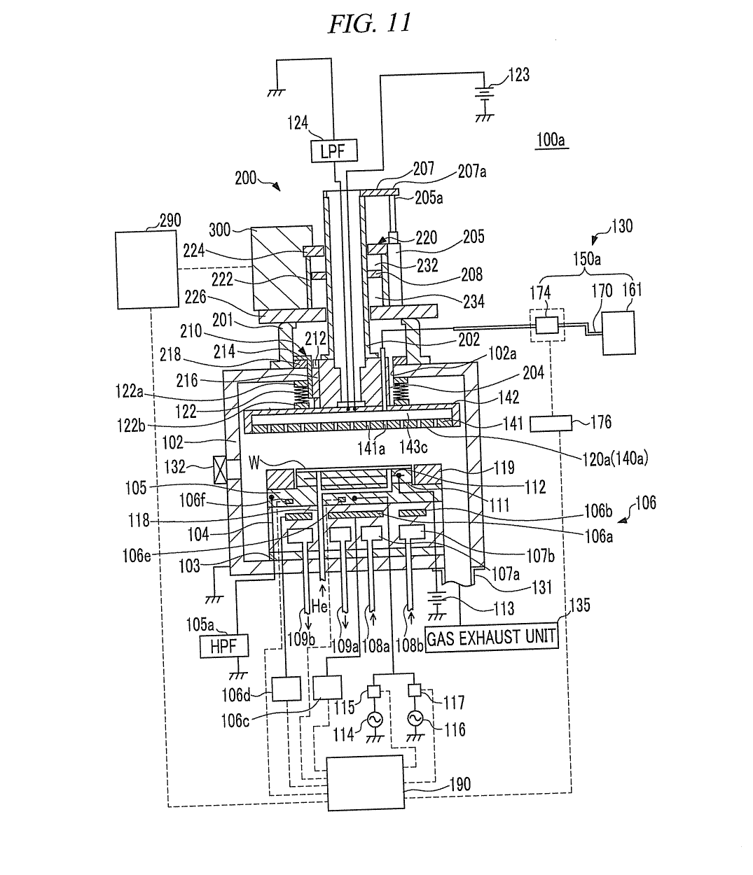

Hereinafter, referring to FIGS. 11 to 15, a plasma etching method and a plasma etching apparatus in accordance with a second embodiment of the present disclosure will be explained.

The present embodiment is different from the first embodiment in that a distribution of a gas supply amount in a wafer surface is not adjusted and a pattern to be formed does not have a sparse area but only has a dense area.

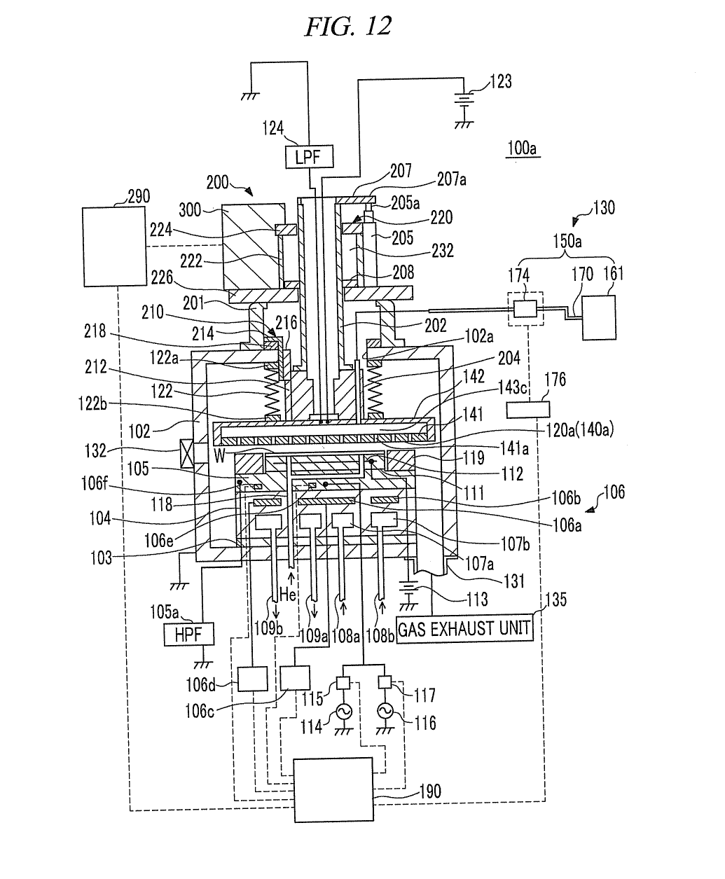

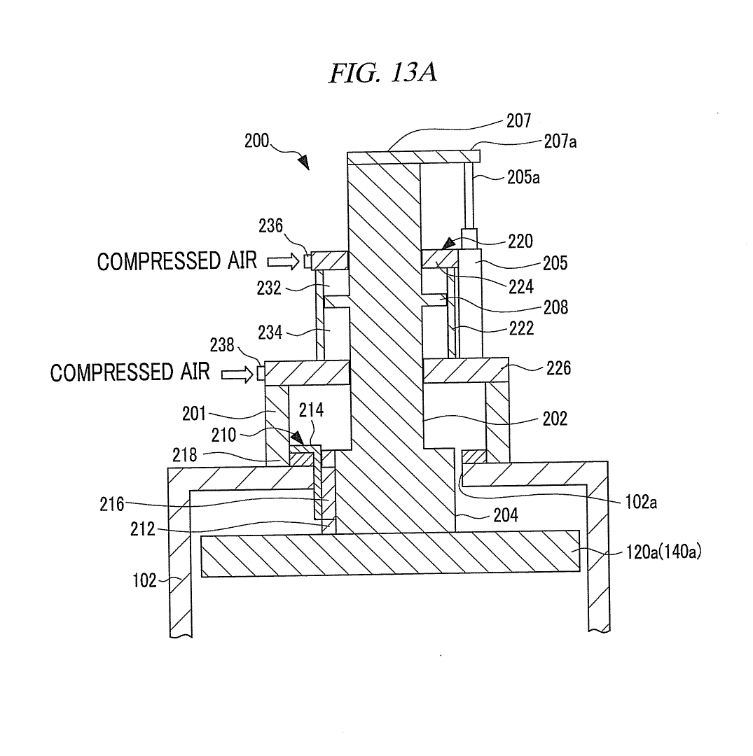

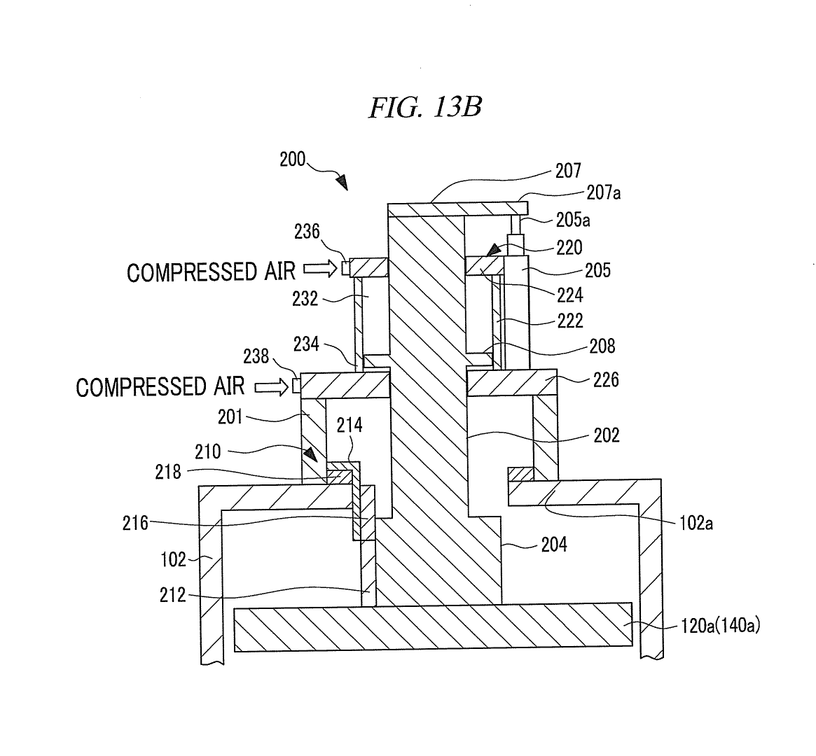

Referring to FIGS. 11 to 15, the plasma etching apparatus in accordance with the present embodiment will be elaborated. FIGS. 11 and 12 are cross sectional views showing a schematic configuration of the plasma etching apparatus in accordance with the present embodiment. To be specific, FIG. 11 shows a configuration in which an upper electrode is located at a retreat position, and FIG. 12 shows a configuration in which the upper electrode is located at a process position. FIGS. 13a and 13b provide explanatory diagrams simply showing an upper electrode driving unit. To be specific, FIG. 13A shows a configuration in which the upper electrode is located at the retreat position and FIG. 13B shows a configuration in which the upper electrode is located at the process position.

As depicted in FIGS. 11 to 13B, a plasma etching apparatus 100a has the same components as those of the plasma etching apparatus 100 explained with reference to FIGS. 1 to 3B except for a shower head 140a (upper electrode 120a) and a gas supply apparatus 150a, and the same components are assigned with same reference numerals as those of the plasma etching apparatus 100 and explanation thereof will be omitted.

The shower head 140a is configured to supply a mixed gas onto the wafer W supported on a susceptor 105. The shower head 140a includes a circular electrode plate 141 (upper electrode 120a) having a multiple number of gas discharge holes 141a and an electrode support body 142 which supports the surface of the electrode plate 141 and is detachable therefrom as explained in the first embodiment. Further, the electrode support 142 and a buffer room 143c are configured in the same manner as the first embodiment.

Meanwhile, in the present embodiment, an annular partition wall member 145 formed of an O-ring is not installed in the buffer room 143c and the buffer room is not divided into plural sections. A bottom surface of the buffer room 140c communicates with gas discharge holes 141a, and the mixed gas can be discharged toward the wafer W. Further, the mixed gas is supplied to the buffer room 143c by a gas supply apparatus 150a.

As depicted in FIGS. 13A and 13B, a detail configuration of the upper electrode driving unit 200 is the same as explained in the first embodiment. However, in the present embodiment, as described below, a mixing line 170 for supplying a gas into the buffer room 143c of the upper electrode 120a is not divided and is configured as a single line. For this reason, a diameter of the bellows 122 may be smaller as compared to that in the first embodiment.

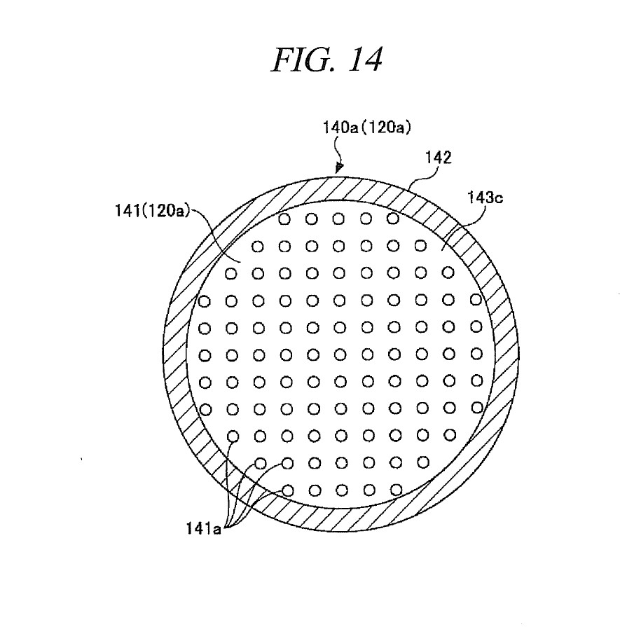

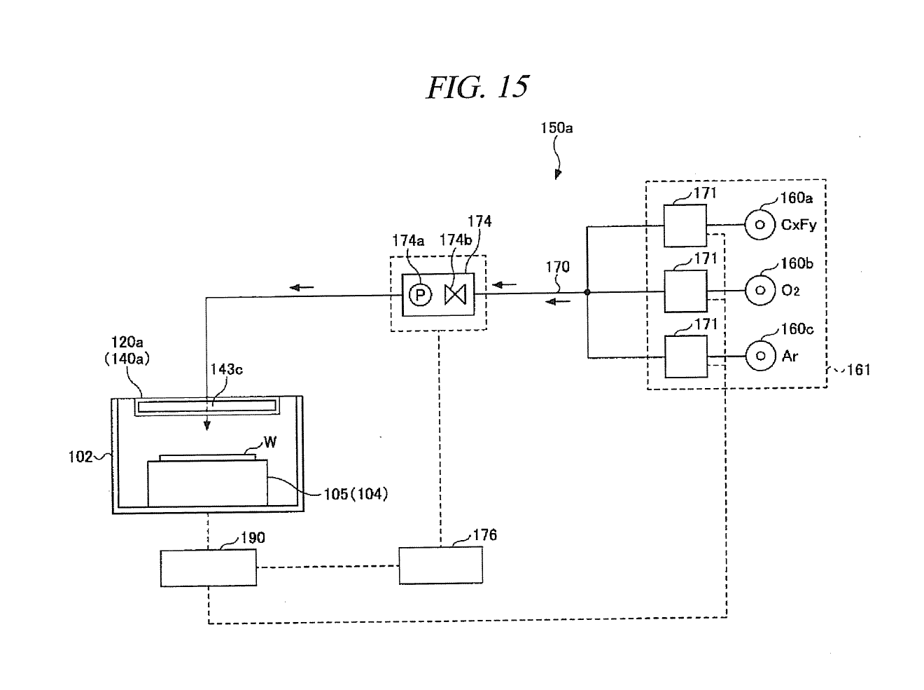

Hereinafter, referring to FIGS. 11, 12, 14 and 15, the gas supply apparatus 150a will be explained. FIG. 14 is transversal cross sectional view of an upper electrode. FIG. 15 is a diagram for explaining a schematic configuration of a gas supply apparatus.

The gas supply apparatus 150a includes a gas box 161 which accommodates a multiple number of, for example, three, gas supply sources 160a, 160b, and 160c. By way of example, a CₓF_{y} gas such as CF₄, C₄F₈, C₄F₈, and C₅F₈ is sealed in a gas supply source 160a, an oxygen (O₂) gas is sealed in a gas supply source 160b, and an Ar gas is sealed in a gas supply source 160c.

Each of the gas supply sources 160a to 160c is connected with the mixing line 170 via a mass flow controller 171. Further, the mixing line 170 is not divided and is connected with the buffer room 143c of the shower head 140a.

A pressure adjusting unit 174 is installed on a part of the mixing line 170, and the pressure adjusting unit 174 includes a pressure gauge 174a and a valve 174b. A measurement result measured by the pressure gauge 174a of the pressure adjusting unit 174 may be outputted by a pressure control apparatus 176. The pressure control apparatus 176 adjusts an opening/closing degree of the valve 174b based on the measurement result of the pressure gauge 174a and controls a flow rate of the processing gas flowing through the mixing line 170.

An operation of the mass flow controller 171 of the gas box 161 is controlled by, for example, an apparatus controller 190 of the plasma etching apparatus 100a. Therefore, the apparatus controller 190 may control a start and a stop of supply of various gases from the gas box 161 and control a supply amount of the various gases.

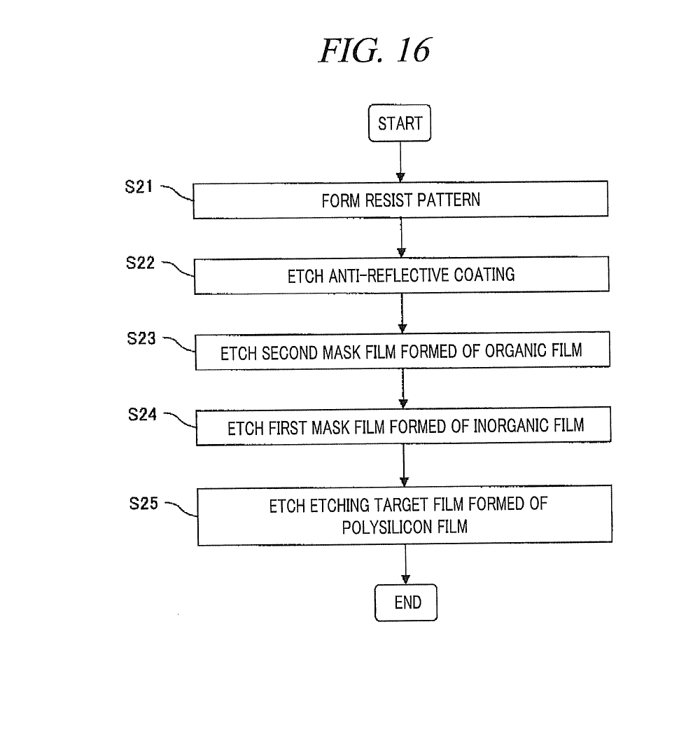

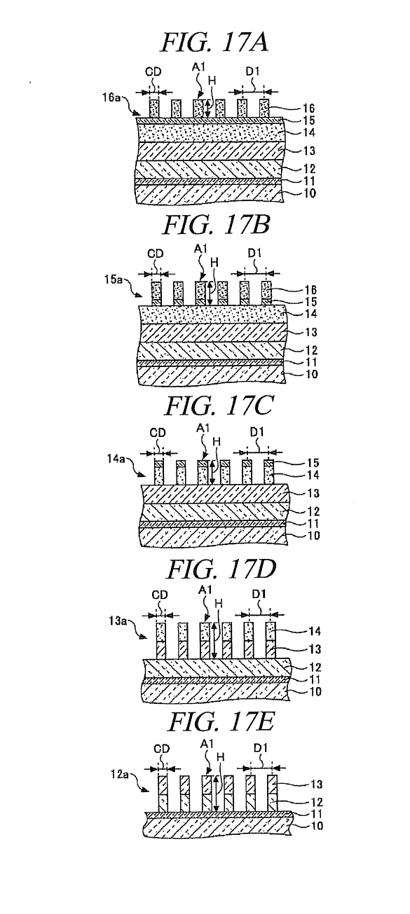

Hereinafter, referring to FIGS. 16 to 17E, a plasma etching method using the plasma etching apparatus 100a will be explained. FIG. 16 is a flowchart for explaining a process sequence of a plasma etching method in accordance with the present embodiment. FIGS. 17A to 17E are cross sectional views schematically showing wafer states in each process of the plasma etching method in accordance with the present embodiment.

The plasma etching method in accordance with the present embodiment, as depicted in FIG. 16, includes a resist pattern forming process (step S21), an anti-reflective coating etching process (step S22), a second mask film etching process (step S23), a first mask film etching process (step S24), and an etching target film etching process (step S25).

First, the resist pattern forming process (step S21) is performed. The resist pattern forming process (step S21) may be performed in the same manner as the resist pattern forming process (step S11) of the first embodiment. FIG. 17A shows a wafer state in the resist pattern forming process (step S21). However, as depicted in FIG. 17a, in the present embodiment, only an area (dense area) A1 in which lines 16a are arranged at a distance D1 is formed and a sparse area is not formed.

Then, the anti-reflective coating etching process (step S22) is performed. The anti-reflective coating etching process (step S22) may be performed in the same manner as the anti-reflective coating etching process (step S12) of the first embodiment. FIG. 17B shows a wafer state in the anti-reflective coating etching process (step S22).

Subsequently, the second mask film etching process (step S23) is performed. In the second mask film etching process (step S23), a second mask film 14 is etched by plasma irradiated to a wafer 10 using lines 15a formed of a resist film 16 and an anti-reflective coating 15, so that lines 14a including the second mask film 14 are formed. FIG. 17C shows a wafer state in the second mask film etching process (step S23).

In the second mask film etching process (step S23), a temperature distribution in the surface of the wafer 10 supported on the susceptor 105 is adjusted. By this adjustment, a distribution of reaction amounts between the radicals of the plasma in the surface of the wafer 10 and the surface of the wafer 10 is controlled. By controlling the distribution of the reaction amounts, it is possible to control a distribution of line widths CD of the lines 14a in the surface of the wafer 10.

In response to a control signal from an apparatus controller 190 to a temperature distribution adjusting unit 106, temperatures of central and outer peripheral thermometers 106e and 106f are adjusted to predetermined temperatures TI and TO, respectively. Further, in response to a control signal from the apparatus controller 190 to the temperature distribution adjusting unit 106, a central heater 106a and an outer peripheral heater 106b are controlled independently. Consequently, it is possible to set the temperature TI at the central area of the wafer 10 to be different from the temperature TO at the outer peripheral area of the wafer 10, and, thus, a temperature distribution in the surface of the wafer 10 can be adjusted.

As described above, by adjusting the temperature distribution in the surface of the wafer 10, it is possible to control the distribution of the line widths CD of the lines 14a formed of the second mask film 14 in the surface of the wafer 10.

In the second mask film etching process (step S23), in response to a control signal from the apparatus controller 190 to an upper electrode driving unit 200, a gap G between the wafer 10 supported on the susceptor 105 and the upper electrode 120a provided so as to face the wafer 10 is adjusted. By adjusting the gap G, it is possible to control a distribution of irradiation amounts of ions in the surface of the wafer 10 and a distribution of etching rates ER in a longitudinal direction (depth direction). Further, by controlling the distribution of the etching rates ER in the longitudinal direction (depth direction), it is possible to control a distribution of heights H of the lines 14a in the surface of the wafer 10.

In the second mask film etching process (step S23), it may be possible to use an oxygen (O₂) gas as the processing gas.

Thereafter, the first mask film etching process (step S24) is performed. In the first mask film etching process (step S24), the first mask film 13 is etched by plasma irradiated to the wafer 10 using the lines 14a formed of the second mask film 14 as a mask, so that lines 13a including the first mask film 13 are formed. FIG. 17D shows a wafer state in the first mask film etching process (step S24).

In the first mask film etching process (step S24), a temperature distribution in the surface of the wafer 10 supported on the susceptor 105 is adjusted. By this adjustment, the distribution of the reaction amounts between the radicals of the plasma in the surface of the wafer 10 and the surface of the wafer 10 is controlled. By controlling the distribution of the reaction amounts, it is possible to control a distribution of the line widths CD of the lines 13a in the surface of the wafer 10.

Further, in the first mask film etching process (step S24), in response to a control signal from the apparatus controller 190 to the upper electrode driving unit 200, a gap G between the wafer 10 supported on the susceptor 105 and the upper electrode 120a provided so as to face the wafer 10 is adjusted. By adjusting the gap G, it is possible to control a distribution of irradiation amounts of ions in the surface of the wafer 10 and a distribution of etching rates ER in a longitudinal direction (depth direction). Further, by controlling the distribution of the etching rates ER in the longitudinal direction (depth direction), it is possible to control a distribution of heights H of the lines 13a in the surface of the wafer 10.

In the first mask film etching process (step S24), as the processing gas, it may be possible to use a mixed gas of a CF-based gas such as CF₄, C₄F₈, CHF₃, CH₃F, and CH₂F₂ with an Ar gas, or the mixed gas further including an oxygen (O₂) gas if necessary.

Thereafter, the etching target film etching process (step S25) is performed in the same manner as the etching target film etching process (step S15) of the first embodiment. FIG. 17E shows a status of a wafer in the etching target film etching process (step S25).

Hereinafter, there will be explained a case where a distribution of line widths CD of lines and a distribution of heights H of the lines in a surface of a wafer are independently controlled and an etching process can be performed with high uniformity in cross sectional shapes of lines when the etching process is performed on the wafer using the plasma etching method in accordance with the present embodiment.

In the present embodiment, it is possible to independently control a distribution of ion fluxes and a distribution of reaction amounts of radicals by using a method of controlling the distribution of ion fluxes by adjusting a gap G and a method of controlling the distribution of the reaction amounts of the radicals by adjusting a temperature distribution in a wafer.

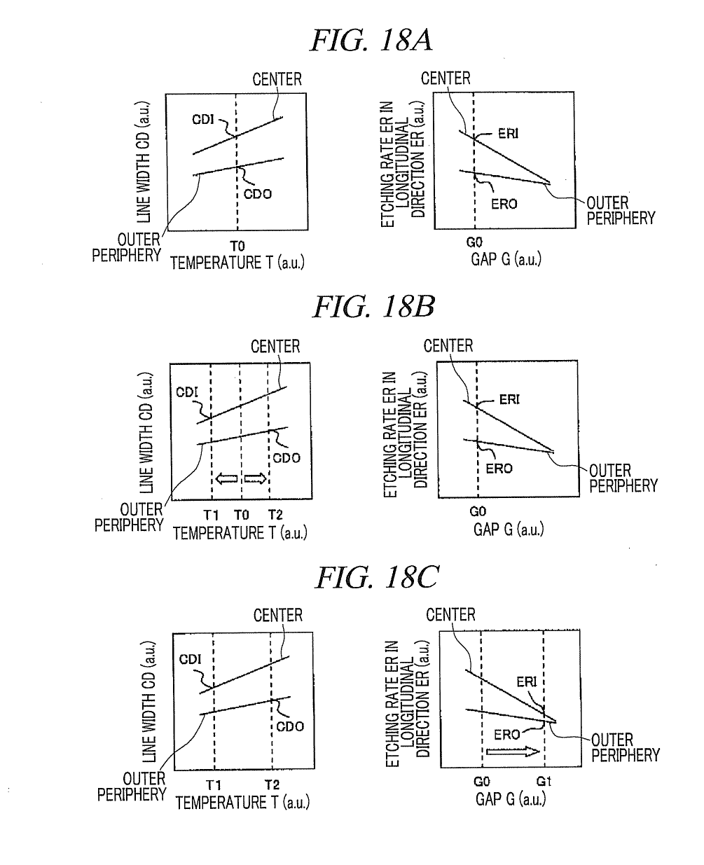

Herein, referring to FIGS. 18A to 18C, there will be explained an example where distributions of line widths CD of lines and the distribution of heights H of lines in the surface of the wafer can be independently controlled.

FIGS. 18A to 18C are graphs schematically showing temperature dependency of line widths CD of lines and gap dependency of etching rates ER in a longitudinal direction in the present embodiment. In each of FIGS. 18A to 18C, the temperature dependency of line widths CD and the gap dependency of the etching rates ER in the longitudinal direction are shown in sequence from the left.

Further, when a temperature distribution, a distribution of a supply amount, and a gap G are adjusted in the second mask film etching process (step S23) and the first mask film etching process (step S24), example processing conditions other than the processing gas are as follows.

### (D) Second Mask Film Etching Process (Step S23)

Material of second mask film: naphthalene (or polystyrene)

Thickness of second mask film: 280 nm

Internal pressure of film forming apparatus: 100 mTorr

High frequency power (40 mHz/13 MHz): 700/0 W

Potential of upper electrode: 0 V

Flow rate of processing gas: N₂/H₂=160/480 sccm

Processing time: 60 seconds

### (E) First Mask Film Etching Process (Step S24)

Material of first mask film: TEOS-SiO₂

Thickness of first mask film: 280 nm

Internal pressure of film forming apparatus: 75 mTorr

High frequency power (40 mHz/13 MHz): 500/0 W

Potential of upper electrode: 300 V

Flow rate of processing gas: CHF₃/CF₄/Ar/O₂=125/225/600/60 sccm (here, CH₂F₂ of 20 sccm may be added to outer peripheral area)

Processing time: 60 seconds

In the present embodiment, when the organic film is etched, a processing gas having a high adhesion coefficient and having radicals of a high reaction rate is used as in the modification example of the first embodiment. Therefore, the second mask film etching process (step S23) and the first mask film etching process (step S24) can be explained with reference to FIGS. 18A to 18C.

FIG. 18A shows each dependency before a temperature distribution and a gap G are adjusted. FIG. 18A shows an example where line widths CD have different temperature dependency at the central area of the wafer and the outer peripheral area of the wafer. Further, in the example shown in FIG. 18A, the etching rates ER in the longitudinal direction have different gap dependency at the central area of the wafer and the outer peripheral area of the wafer.

FIG. 18B shows each dependency after the temperature distribution is adjusted. As depicted in FIG. 18B, the temperature TI at the central area is set to be T1 lower than T0 and the temperature TO at the outer peripheral area is set to be T2 higher than T0. In this way, by adjusting the temperature distribution in the surface of the wafer, a difference between the line width CDI at the central area and the line width CDO at the outer peripheral area can be further reduced.

FIG. 18C shows each dependency after the gap G is adjusted. In the example shown in FIG. 18C, the gap is set to be G1 greater than G0. Thus, a difference between the etching rate ERI in the longitudinal direction at the central area and the etching rate ERO in the longitudinal direction at the outer peripheral area can be further reduced. Therefore, after the distribution of the reaction amount of the radicals in the wafer surface is adjusted, the etching rate ER in the longitudinal direction in the wafer surface may be adjusted.

In the present embodiment, it may be possible to use a mask film including inorganic and organic films capable of increasing selectivity in etching rates for each processing gas when the processing gas is varied. Thus, it may be possible to transfer a shape of a resist pattern onto an etching target film with high accuracy and also possible to uniform a distribution of shapes of lines formed of the etching target film in the wafer surface.

Further, the present embodiment can be applied to a case where a mask film includes only a single film and in this case, it is also possible to uniform a distribution of shapes of lines formed of an etching target film in a wafer surface.

As described above, there have been explained embodiments of the present disclosure, but the present invention is not limited to the above-described embodiments and can be modified and changed in various ways within a scope of the following claims.

What is claimed is:

1. A plasma etching method for performing a plasma etching on a substrate by irradiating plasma containing charged particles and neutral particles to the substrate, the method comprising:
controlling a distribution of reaction amounts between the substrate and the neutral particles in a surface of the substrate by adjusting a temperature distribution in the surface of the substrate supported by a support; and
controlling a distribution of irradiation amounts of the charged particles in the surface of the substrate by adjusting a gap between the substrate supported by the support and an electrode provided so as to face the support.

2. The plasma etching method of claim 1, further comprising:
an etching process for forming lines including a mask film by etching the mask film formed on the substrate by the irradiated plasma,
wherein, in the etching process, a distribution of line widths of the lines in the surface of the substrate is controlled by adjusting the distribution of reaction amounts, and a distribution of heights of the lines in the surface of the substrate is controlled by adjusting the distribution of irradiation amounts.

3. The plasma etching method of claim 2, wherein the etching process includes:
a second mask film etching process for forming the lines including a second mask film by irradiating first plasma containing first charged particles and first neutral particles to the substrate and etching the second mask film formed on the substrate via a first mask film by the irradiated first plasma; and
a first mask film etching process for forming the lines including the first mask film by irradiating second plasma containing second charged particles and second neutral particles to the substrate on which the lines including the second mask film are formed and etching the first mask film by the irradiated second plasma,
wherein temperature dependency of a reaction amount between the second mask film and the first neutral particles is lower than temperature dependency of a reaction amount between the first mask film and the second neutral particles.

4. The plasma etching method of claim 1, wherein the distribution of reaction amounts in the surface of the substrate is controlled by adjusting the temperature distribution and a distribution of a supply amount or a composition ratio of a processing gas supplied to the substrate.

5. The plasma etching method of claim 4, further comprising:
an etching process for forming first lines including a mask film and spaced apart from each other at a first gap and second lines including the mask film and spaced apart from each other at a second gap greater than the first gap by etching the mask film formed on the substrate by the irradiated plasma,
wherein, in the etching process, a distribution of line widths of the first lines and the second lines in the surface of the substrate is controlled by adjusting the distribution of reaction amounts, and a distribution of heights of the first lines and the second lines in the surface of the substrate is controlled by adjusting the distribution of irradiation amounts, and
temperature dependency of a first reaction amount between the first lines and the neutral particles is lower than temperature dependency of a second reaction amount between the second lines and the neutral particles.

6. The plasma etching method of claim 5, wherein the etching process includes:
a second mask film etching process for forming the first lines and the second lines each including a second mask film by irradiating first plasma containing first charged particles and first neutral particles to the substrate and etching the second mask film formed on the substrate via a first mask film by the irradiated first plasma; and
a first mask film etching process for forming the first lines and the second lines each including the first mask film by irradiating second plasma containing second charged particles and second neutral particles to the substrate on which the first lines and the second lines each including the second mask film are formed and etching the first mask film by the irradiated second plasma,
wherein temperature dependency of a reaction amount between the second mask film and the first neutral particles is lower than temperature dependency of a reaction amount between the first mask film and the second neutral particles.

7. The plasma etching method of claim 3, wherein the first mask film includes an inorganic film and the second mask film includes an organic film, and
the first neutral particles include oxygen radicals and the second neutral particles include fluorine radicals.

8. The plasma etching method of claim 6, wherein the first mask film includes an inorganic film and the second mask film includes an organic film, and
the first neutral particles include oxygen radicals and the second neutral particles include fluorine radicals.
